(19) United States
(12) Patent Application Publication
(10) Pub. No.: US 2018/0022881 A1
(43) Pub. Date: Jan. 25, 2018

(54) FUNCTIONAL FILM AND METHOD FOR PRODUCING FUNCTIONAL FILM

(71) Applicant: FUJIFILM Corporation, Tokyo (JP)

(72) Inventors: Tomokazu SEKI, Minami-ashigara-shi (JP); Eijiro IWASE, Minami-ashigara-shi (JP)

(73) Assignee: FUJIFILM Corporation, Tokyo (JP)

(21) Appl. No.: 15/714,482

(22) Filed: Sep. 25, 2017

Related U.S. Application Data
(63) Continuation of application No. PCT/JP2016/057603, filed on Mar. 10, 2016.

(30) Foreign Application Priority Data
Mar. 26, 2015 (JP) 2015-064327

(51) Int. Cl. C08J 5/18; G02B 5/02; F21K 9/64; H01L 33/50; C09J 175/04; F21V 8/00; B32B 7/02; B05D 5/06; C09J 11/06

(52) U.S. Cl. CPC C08J 5/18; B05D 5/06; G02B 5/021; F21K 9/64; C09J 11/06; C09J 175/04; G02B 6/0053; G02B 6/0061; B32B 7/02; H01L 33/502

(57) ABSTRACT

A functional film including a substrate, a first functional layer having one or more combinations of an inorganic layer and an organic layer serving as a base substrate of the inorganic layer, formed on one surface of the substrate, a functional layer-side surface layer formed on the surface of the first functional layer, with the surface being on the side opposite to the substrate, a light diffusion layer formed on the surface of the substrate, with the surface being on the side opposite to the surface on which a first functional layer is formed, and a diffusion layer-side surface layer having a support and an adhesive layer, formed on the surface of the light diffusion layer; and a method for producing the same are provided. Thus, a functional film which has a light diffusion layer and is suitably used for a quantum dot film or the like is provided.

### CROSS-REFERENCE TO RELATED APPLICATIONS

This application is a Continuation of PCT International Application No. PCT/JP2016/057603 filed on March 10, 2016, which claims priority under 35 U.S.C. §119(a) to Japanese Patent Application No. 2015-064327 filed on Mar. 26, 2015. The above application is hereby expressly incorporated by reference, in its entirety, into the present application.

### BACKGROUND OF THE INVENTION

### 1. Field of the Invention

The present invention relates to a functional film which exerts good light diffusing properties and adhesiveness, and a wavelength conversion film using the functional film.

### 2. Description of the Related Art

A liquid crystal display device has been used more widely year by year as a space-saving image display device with low power consumption. Further, recently, as an improvement in performance for liquid crystal display devices, there have been demands for further power saving, enhancement in color reproducibility, and the like. In the following description, a “liquid crystal display device” is also referred to as an “LCD”.

It has been proposed to use quantum dots which emit light by conversion of the wavelength of incidence ray in order to enhance light utilization efficiency and improve color reproducibility in response to a demand for power saving with respect to the backlight of an LCD.

Quantum dots are in the state of electrons having a limited moving direction in all three-dimensional directions, and in a case where nanoparticles of a semiconductor are three-dimensionally surrounded by high-potential barriers, these nanoparticles become quantum dots. The quantum dots express various quantum effects. For example, a so-called quantum size effect in which the densities of states (energy levels) of the electrons are discretized is expressed. According to this quantum size effect, the absorption wavelength/emission wavelength of light can be controlled by changing the sizes of the quantum dots.

Generally, such quantum dots are dispersed in a binder formed of resins such as an acrylic resin and an epoxy resin to become a quantum dot layer, which is disposed between a backlight and a liquid crystal panel, and used, for example, as a wavelength conversion film which performs wavelength conversion.

In a case where excitation light is incident to a quantum dot layer from the backlight, the quantum dots are excited to emit fluorescent light. Here, white light can be realized by emitting light having a narrow half width, such as red light, green light, and blue light, by employing quantum dots having different light emission characteristics. Since the fluorescent light derived from quantum dots has a narrow half width, it is possible to make a design such that the white light obtained by appropriately selecting the wavelength can be designed to have a high brightness or excellent color reproducibility.

However, the quantum dots have problems in that they are easily deteriorated by moisture or oxygen and have a reduction in light emission intensity due to a photo-oxidation reaction. Thus, protection of the quantum dot layer has been carried out by laminating gas barrier films on both surfaces of the quantum dot layer.

For example, JP2013-544018A describes a laminated wavelength conversion film (quantum dot film) in which quantum dots are protected by sandwiching a quantum dot layer between two gas barrier films, as a backlight unit for use in an LCD or the like.

Furthermore, JP2013-544018A describes a configuration in which an oxide layer expressing gas barrier properties, such as silicon oxide, titanium oxide, and aluminum oxide, is formed on a substrate serving as a resin film such as a polyethylene terephthalate (PET) film as gas barrier films having a quantum dot layer sandwiched therebetween.

In addition, JP2013-544018A also describes that a light diffusion layer (layer having scattering particles) is provided in a portion other than the quantum dot layer.

On the other hand, an organic-inorganic laminated gas barrier film having one or more combinations having an inorganic layer and an organic layer serving as a base substrate of the inorganic layer on a substrate as described in JP2011-167967A is known as a gas barrier film having excellent gas barrier properties.

In the organic-inorganic laminated gas barrier film, there is the inorganic layer that mainly exerts gas barrier properties. In the organic-inorganic laminated gas barrier film, it is possible to form a high-quality inorganic layer without cracks, damages, or the like due to incorporation of an organic layer serving as a base substrate. As a result, the performance of the inorganic layer is sufficiently expressed, and thus, highly excellent gas barrier properties are obtained.

Therefore, by sandwiching a quantum dot layer between the organic-inorganic laminated gas barrier films, it is expected that deterioration of the quantum dot layer due to moisture can be more suitably prevented.

### SUMMARY OF THE INVENTION

The present inventors have expected that provision of a light diffusion layer in addition to a quantum dot layer leads to an increase in the amount of light emitted from the quantum dot layer, whereby the brightness of an LCD can be improved, as shown in JP2013-544018A, and they have repeatedly conducted the studies.

As a result, it has been demonstrated that t is possible to improve the brightness, as compared with a case where there is no light diffusion layer, by providing a light diffusion layer in a wavelength conversion film having a quantum dot layer. In a case where such the improvement of brightness can be attained, it can be expected that a clear image with high brightness is displayed by an LCD, lower cost due to reduction in the amount of quantum dots to be used for accomplishing a certain degree of brightness is accomplished, or a thinner backlight unit can be produced with a thinner quantum dot layer.

With regard to a configuration for sandwiching a quantum dot layer between gas barrier films, a quantum dot layer is sandwiched between gas barrier films while the gas barrier layer is arranged to face the side of the quantum dot layer, as shown in JP2013-544018A, in order to keep quantum dots from moisture more reliably. That is, with the gas barrier films described in JP2013-544018A, the quantum dot layer is sandwiched between the gas barrier films the oxide layer is arranged to face the inner side, while with the gas barrier films described in JP2011-167967A, the quantum dot layer is sandwiched between the gas barrier films while an organic/inorganic laminated structure is arranged to face the inner side.

Accordingly, in this case, the light diffusion layer is formed on the surface of the substrate of one of the gas barrier films, with the surface being on the side opposite to the surface on which the gas barrier layer is formed.

Meanwhile, according to the studies of the present inventors, particularly in the gas barrier films expressing gas barrier properties by an inorganic layer, in a case where a light diffusion layer is formed on the surface of the substrate, with the surface being on the side opposite to the surface on which the gas barrier layer is formed, the inorganic layer is damaged, and as a result, gas barrier properties desirable for the gas barrier films cannot be expressed in many cases.

With an aim to solve such problems in the related art, the present invention has an object to provide a functional film which has light diffusing properties and is capable of stably expressing a function for the purposes of excellent gas barrier properties and the like, and a method for producing the functional film.

In order to solve the problems, a first aspect of the functional film of the present invention provides a functional film comprising:

a substrate;

a first functional layer having one or more combinations of an inorganic layer and an organic layer serving as a base substrate of the inorganic layer, formed on one surface of the substrate;

a functional layer-side surface layer formed on the surface of the first functional layer, with the surface being on the side opposite to the substrate;

a light diffusion layer formed on the substrate, with the surface being on the side opposite to the surface on which the first functional layer is formed; and

a diffusion layer-side surface layer having a support and an adhesive layer, formed on the surface of the light diffusion layer.

Furthermore, a second aspect of the functional film of the present invention provides a functional film comprising:

a substrate;

a first functional layer having one or more combinations of an inorganic layer and an organic layer serving as a base substrate of the inorganic layer, formed on one surface of the substrate;

a second functional layer formed on the surface of the first functional layer, with the surface being on the side opposite to the substrate;

a light diffusion layer formed on the surface of the substrate, with the surface being on the side opposite to the surface on which the first functional layer is formed; and

a diffusion layer-side surface layer having a support and an adhesive layer, formed on the surface of the light diffusion layer.

In the second aspect of such the functional film of the present invention, it is preferable that the second functional layer is an adhesion layer.

Moreover, a third aspect of the functional film of the present invention provides a functional film comprising:

a functional film including a substrate, a first functional layer having one or more combinations of an inorganic layer and an organic layer serving as a base substrate of the inorganic layer, formed on one surface of the substrate, a light diffusion layer formed on the surface of the substrate, with the surface being on the side opposite to the surface on which the first functional layer is formed, and a diffusion layer-side surface layer having a support and an adhesive layer, formed on the surface of the light diffusion layer;

a gas barrier film; and

a quantum dot layer sandwiched between the functional film and the gas barrier film, with the diffusion layer-side surface layer of the functional film being on the outer side.

In the third aspect of such the functional film of the present invention, it is preferable that the gas barrier film has a substrate and one or more combinations of an inorganic layer and an organic layer serving as a base substrate of the inorganic layer, formed on one surface of the substrate, and the substrate is on the outer side.

In addition, it is preferable that the adhesion layer is included at least one of between the functional film and the quantum dot layer, or between the gas barrier film and the quantum dot layer.

Furthermore, as a method for producing a functional film of the present invention, provided is a method for producing a functional film, comprising:

a step of forming a first functional layer having one or more combinations of an inorganic layer and an organic layer serving as a base substrate of the inorganic layer, on one surface of a substrate;

a step of forming a functional layer-side surface layer on the surface of the first functional layer, with the surface being on the side opposite to the substrate;

a step of forming a light diffusion layer on the surface of the substrate, with the surface being on the side opposite to the surface on which the first functional layer is formed after forming the functional layer-side surface layer; and

a step of forming a diffusion layer-side surface layer having a support and an adhesive layer, on the surface of the light diffusion layer.

It is preferable that such the method for producing a functional film of the present invention further comprises a step of peeling the functional layer-side surface layer.

Furthermore, it is preferable that the method further comprises a step of forming a second functional layer on the surface of the first functional layer, with the surface being on the side opposite to the substrate.

Moreover, it is preferable that the second functional layer is an adhesion layer.

Incidentally, it is preferable that the method further comprises a step of applying a composition serving as a quantum dot layer on the outermost surface on the side having the first functional layer formed thereon and laminating a gas barrier film on the surface of the composition, or a step of applying a composition serving as a quantum dot layer on the surface of the gas barrier film, laminating a functional film on the surface of the composition while the first functional layer is arranged to face the composition, and a step of curing the composition.

Furthermore, it is preferable that the gas barrier film has a substrate and one or more combinations of an inorganic layer and an organic layer serving as a base substrate of the inorganic layer, formed on one surface of the substrate, and the surface on which the organic layer and the inorganic layer are formed is on the composition side.

Moreover, it is preferable that the gas barrier film has the adhesion layer on the outermost surface.

Incidentally, it is preferable that the method further comprises a step of peeling the diffusion layer-side surface layer.

According to the present invention, a functional film which has light diffusing properties and stably expresses a function for the purposes of gas barrier properties and the like is obtained.

### BRIEF DESCRIPTION OF THE DRAWINGS

FIG. 1 is a view conceptually showing an example of a functional film of the present invention.

FIG. 2 is a view conceptually showing another example of the functional film of the present invention.

FIG. 3 is a view conceptually showing still another example of the functional film of the present invention.

### DESCRIPTION OF THE PREFERRED EMBODIMENTS

Hereinbelow, the functional film and the method for producing a functional film of the present invention will be described in detail with reference to suitable Examples shown in the accompanying drawings.

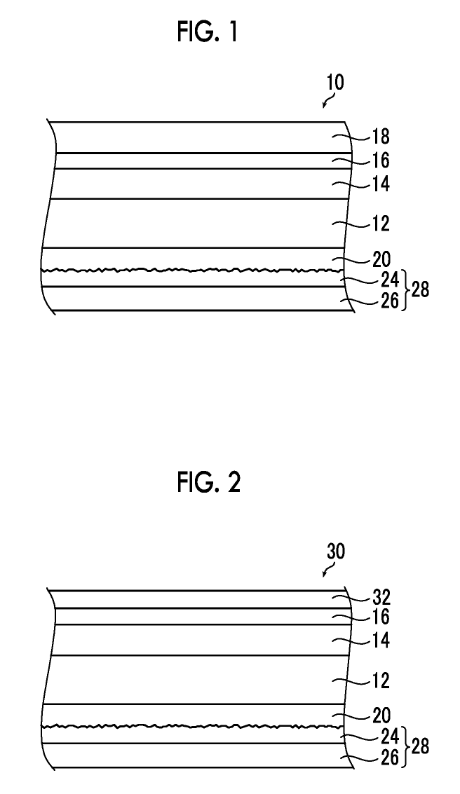

FIG. 1 conceptually shows an example in which a functional film of the present invention is used in a gas barrier film.

In addition, the functional film of the present invention is not limited to the gas barrier film. That is, the functional film of the present invention can be used in any of various known functional films, including, for example, various optical films such as filters that transmit light at a specific wavelength and antireflection films as long as these films require light diffusing properties.

Here, the functional film of the present invention has a diffusion layer-side surface layer on the light diffusion layer. Due to incorporation of the diffusion layer-side surface layer, the diffusion layer-side surface layer acts as a protective layer, for example, even in a case of being wound by roll-to-roll which will be described later, and as a result, damages on the inorganic layer due to the light diffusion layer can be prevented. This will be described later. In the following description, the “roll-to-roll” is also referred to as “R-to-R”.

Therefore, the functional film of the present invention is more suitably used in a gas barrier film having much deteriorated performance due to the damages on the inorganic layer.

The gas barrier film 10 shown in FIG. 1 basically has a substrate 12, an organic layer 14 formed on the one surface of the substrate 12, an inorganic layer 16, and a first protective film 18. Further, the gas barrier film 10 has a light diffusion layer 20 formed on the surface of the substrate 12, with the surface being on the side opposite to the surface on which the inorganic layer 16 or the like is formed, and a second protective film 28.

Although being described later, the organic layer 14 is a layer serving as a base substrate of the inorganic layer 16, and the organic layer 14 constitutes the first functional layer in the present invention, together with the inorganic layer 16. Accordingly, the first protective film 18 formed on the inorganic layer 16 is a functional layer-side surface layer in the present invention. Further, the position on the inorganic layer 16 refers to the surface of the inorganic layer 16, with the surface being on the side opposite to the substrate 12. In addition, in the examples as illustrated, the first functional layer is a gas barrier layer.

The second protective film 28 formed on the light diffusion layer 20 is a diffusion layer-side surface layer in the present invention. Accordingly, the second protective film 28 has a support 26 and an adhesive layer 24. Further, the position on the light diffusion layer 20 refers to the surface of the light diffusion layer 20, with the surface being on the side opposite the substrate 12.

That is, the gas barrier film 10 shown in FIG. 1 has one combination of the organic layer 14 and the inorganic layer 16. However, the functional film of the present invention can also use various configurations other than those above.

For example, the functional film may have two combinations of the organic layer 14 and the inorganic layer 16, or may have three or more combinations of the organic layer 14 and the inorganic layer 16.

Alternatively, the functional film may be configured to have the inorganic layer 16 on the surface of the substrate 12, and have one or more combinations of the organic layer 14 and the inorganic layer 16 thereon.

That is, in the functional film of the present invention, any of various configurations can be used as long as the first functional layer formed on one surface of the substrate 12 has one or more combinations of the inorganic layer 16 and the organic layer 14 serving as a base substrate of the inorganic layer 16, and the uppermost layer, that is, the underlayer of the first protective film (functional layer-side surface layer) serves as an inorganic layer.

In the gas barrier film 10, various known materials in a sheet form, which are used as a substrate (support) in various gas barrier films or various laminated functional films, can be used as the substrate 12.

Specific suitable examples of the substrate 12 include films (resin films) formed of various resin materials, such as low-density polyethylene (LDPE), high-density polyethylene (HDPE), polyethylene naphthalate (PEN), polyamide (PA), polyethylene terephthalate (PET), polyvinyl chloride (PVC), polyvinyl alcohol(PVA), polyacrylonitrile (PAN), polyimide(PI), transparent polyimide, a methyl polymethacrylate resin (PMMA), polycarbonate (PC), polyacrylate, polymethacrylate, polypropylene (PP), polystyrene (PS), ABS, a cyclic olefin/copolymer (COC), a cycloolefin polymer (COP), and triacetyl cellulose (TAC).

In the present invention, a support having a layer (film) expressing necessary functions, such as a protective layer, an adhesive layer, a light reflecting layer, an antireflection layer, a light shielding layer, a planarizing layer, a buffer layer, and a stress relaxation layer, formed on the surface of such the film, is used as the substrate 12.

The thickness of the substrate 12 may be appropriately set, depending on applications, forming materials, or the like of the gas barrier film 10.

According to the studies of the present inventors, the thickness of the substrate 12 is preferably 5 to 100 μm, and more preferably 10 to 50 μm.

It is preferable to set the thickness of the substrate 12 within the above range, for example, in views that the mechanical strength of the gas barrier film 10 is sufficiently secured, and further, the gas barrier film 10 can be lighter, thinner, and flexible. Further, by setting the thickness of the substrate 12 within the above range, the functional film of the present invention can be made thinner in a case where it is used in a quantum dot film or the like.

The organic layer 14 is a layer formed of organic compounds, which is basically obtained by the polymerization (crosslinking) of monomers or oligomers serving as the organic layer 14.

The organic layer 14 on the surface of the substrate 12 functions as an underlying layer for properly forming an inorganic layer 16 which usually expresses gas barrier properties in the gas barrier film 10.

By incorporation of such an organic layer 14, the surface unevenness of the substrate 12 (or the inorganic layer 16 of the underlayer), the foreign substance attached to the surface of the substrate 12, and the like can be embedded to bring the deposition surface of the inorganic layer 16 into a state which is suitable for forming the inorganic layer 16. Thus, it is possible to remove regions in which it is difficult for an inorganic compound which becomes the inorganic layer 16 to deposit a film, such as unevenness and shadows of foreign substance on the surface of the substrate 12, thereby forming a proper inorganic layer 16 without gaps on the entire surface of the substrate.

In the gas barrier film 10, the forming materials of the organic layer 14 are not limited and various known organic compounds can be used.

Suitable specific examples thereof include thermoplastic resins such as polyesters, (meth)acrylic resins, methacrylic acid-maleic acid copolymers, polystyrene, transparent fluororesins, polyimide, fluorinated polyimide, polyamide, polyamideimide, polyetherimide, cellulose acylate, polyurethane, polyether ether ketone, polycarbonate, alicyclic polyolefin, polyarylate, polyether sulfone, polysulfone, fluorene ring-modified polycarbonate, alicyclic-modified polycarbonate, fluorene ring-modified polyester, and acrylic compounds; and films of polysiloxane and other organosilicon compounds. A plurality of these compounds may be used in combination.

Among those, the organic layer 14 constituted with polymerized products of radically curable compounds and/or cationically curable compounds having an ether group as a functional group is suitable in views of excellent glass transition temperature or strength, and the like.

Among those, in particular, in views of a low refractive index, high transparency, excellent optical characteristics, and the like, acrylic resins or methacrylic resins having polymers of the monomers or oligomers of acrylate and/or methacrylate as a main component are suitably exemplified as the organic layer 14.

Among those, in particular, acrylic resins or methacrylic resins having bifunctional or higher, in particular, trifunctional or higher polymers of the monomers or the oligomers of acrylate and/or methacrylate as a main component, such as dipropylene glycol di(meth)acrylate (DPGDA), trimethylolpropane tri(meth)acrylate (TMPTA), and dipentaerythritol hexa(meth)acrylate (DPHA) are suitably exemplified. Further, it is also preferable that a plurality of these acrylic resins or methacrylic resins are used.

The thickness of the organic layer 14 may be appropriately set, depending on the forming materials of the organic layer 14 or the substrate 12. According to the studies of the present inventors, the thickness of the organic layer 14 is preferably set to 0.5 to 5 μm, and more preferably set to 1 to 3 μm.

Therefore, by setting the thickness of the organic layer 14 to 0.5 μm or more, the surface unevenness of the substrate 12 or the foreign substance attached to the surface of the substrate 12 can be embedded to planarize the surface of the organic layer 14, that is, the deposition surface of the inorganic layer 16.

Furthermore, by setting the thickness of the organic layer 14 to 5 μm or less, occurrence of problems such as cracking of the organic layer 14 due to the excessively large thickness of the organic layer 14, and curling of the gas barrier film 10 can be suitably suppressed.

Moreover, in a case where a plurality of the organic layers 14 are included as described above, the thickness of the respective organic layers 14 may be the same as or different from each other. Further, the forming materials of the respective organic layers 14 may be the same as or different from each other.

The inorganic layer 16 is a layer formed of inorganic compounds.

In the gas barrier film 10, the inorganic layer 16 usually expresses the desired gas barrier properties.

The forming materials of the inorganic layer 16 are not limited and various layers formed of inorganic compounds expressing gas barrier properties can be used.

Specifically, films formed of inorganic compounds including metal oxides such as aluminum oxide, magnesium oxide, tantalum oxide, zirconium oxide, titanium oxide, and indium tin oxide (ITO); metal nitrides such as aluminum nitride; metal carbides such as aluminum carbide; oxides of silicon such as silicon oxide, silicon oxynitride, silicon oxycarbide, and silicon oxynitrocarbide; nitrides of silicon such as silicon nitride and silicon nitrocarbide; carbides of silicon such as silicon carbide; hydrides thereof; and hydrogenated products thereof are suitably exemplified. Further, a mixture of two or more thereof can also be used.

Particularly, silicon nitride, silicon oxide, silicon oxynitride, aluminum oxide, and a mixture of two or more thereof are suitably used since they have high transparency and are capable of expressing excellent gas barrier properties. Among these, in particular, silicon nitride is suitably used since it has high transparency as well as excellent gas barrier properties.

As the film thickness of the inorganic layer 16, a thickness capable of expressing gas barrier properties may be appropriately determined, depending on the forming materials. According to the studies of the present inventors, the thickness of the inorganic layer 16 is preferably 10 to 200 nm, more preferably 15 to 100 nm, and particularly preferably 20 to 75 nm.

By setting the thickness of the inorganic layer 16 to 10 nm or more, the inorganic layer 16 which stably expresses sufficient gas barrier performance can be formed. Further, the inorganic layer 16 is generally brittle, and thus, in a case where it is excessively thick, it can cause generation of cracks, lines, peeling, or the like, whereas by setting the thickness of the inorganic layer 16 to 200 nm or less, generation of cracks can be prevented.

Moreover, in a case of a plurality of inorganic layers 16 are included as described above, the thickness of the respective inorganic layers 16 may be the same as or different from each other. Further, the forming materials of the respective inorganic layers 16 may be the same as or different from each other.

In the gas barrier film 10, the first protective film 18 is laminated on the inorganic layer 16 of the uppermost layer.

The first protective film 18 is intended to protect the inorganic layer 16 on the uppers side of the inorganic layer 16 of the uppermost layer, that is, on the surface side of inorganic layer 16.

Furthermore, an antistatic layer, an a antireflection layer, an anti-Newton ring layer, or the like may be provided, as desired, between the inorganic layer 16, and the first protective film 18 and the adhesion layer 32 which will be described later.

For the first protective film 18, various known ones that are used as a protective film (protective layer) of a functional film in a gas barrier film or the like can be used.

In addition, usually, the first protective film 18 is finally peeled at the time of using the gas barrier film 10. Accordingly, it is preferable that the first protective film 18 has necessary adhesiveness as well as good peelability, with respect to the inorganic layer 16.

Examples of such the first protective film 18 include a film obtained by forming an adhesive layer on the surface of the resin film exemplified for the substrate 12, or the like.

The adhesive layer is not particularly limited, and for example, various adhesive layers including known adhesives which are used in adhesive films can be used. Specifically, various known adhesive layers, such as an ethylene-vinyl acetate copolymer-based adhesive material, a polyolefin-based adhesive material, an acrylic adhesive material, a rubber-based adhesive material, a urethane-based adhesive material, a silicone-based adhesive material, and an ultraviolet-curable adhesive material can be used.

In addition, as the first protective film 18, various commercially available adhesive films which are used as a protective film in a functional film such as a gas barrier film can also be suitably used.

The thickness of the first protective film 18 may be appropriately set, depending on applications of the gas barrier film 10, the protection performance required for the first protective film 18, or the like.

According to the studies of the present inventors, the thickness is preferably 20 to 100 μm, and more preferably 30 to 70 μm.

It is preferable to set the thickness of the first protective film 18 to 20 μm or more, for example, in views that generation of wrinkles at the time of attaching the second protective film 28 capable of suitably protecting the inorganic layer 16 onto the light diffusion layer 20 formed on the surface on the side opposite to the substrate 12 can be prevented.

It is preferable to set the thickness of the first protective film 18 to 100 μm or less, for example, in views that the gas barrier film 10 can be prevented from being unnecessarily thickened, the weight of the gas barrier film 10 can be reduced, and the diameter of the roll at the time of winding the gas barrier film 10 can further be reduced.

The adhesion force between the inorganic layer 16 and the first protective film 18 may be an adhesion force such that the first protective film 18 is prevented from being unnecessarily peeled, depending on the applications of the gas barrier film 10, the strength of the inorganic layer 16, or the like, and the inorganic layer 16 can be peeled while not causing damages.

According to the studies of the present inventors, the adhesion force between the inorganic layer 16 and the first protective film 18 is preferably 0.02 to 0.06 N/25 mm.

It is preferable to set the adhesion force of the first protective film 18 to 0.02 N/25 mm or more, for example, in views that the first protective film 18 can be suitably prevented from being unnecessarily peeled.

It is preferable to set the adhesion force of the first protective film 18 to 0.06 N/25 mm or less, for example, in views that the first protective film 18 can be peeled while not applying a load onto the inorganic layer 16.

In addition, in the present invention, the adhesion force may be measured in accordance with an 180° peeling test method of JIS Z 0237 2009.

In the gas barrier film 10, a light diffusion layer 20 is formed on the surface of the substrate 12, with the surface being on the side opposite to the surface on which the organic layer 14, the inorganic layer 16, and the first protective film 18 are formed.

Incorporation of the light diffusion layer 20 into the gas barrier film 10 leads to an increase in the amount of excited light incident to the quantum dot layer or the amount of light emitted from the quantum dot layer in the quantum dot film which will be described later, and the like, whereby it is possible to improve the brightness of an LCD or the like.

The light diffusion layer 20 is formed by dispersing a light diffusing agent in a binder (matrix).

As the binder, various binders which are used in a light diffusion layer formed by dispersing a light diffusing agent in a binder can be used. That is, in the light diffusion layer 20, various known materials for the binder can be used as long as the refractive index n1 of the binder and the refractive index n2 of the light diffusing agent satisfy a relationship of n1>n2.

Specifically, from the viewpoint of productivity or the like, it is preferable that a light scattering, layer is formed as a curing layer of a polymerizable composition (curable composition) including light scattering particles and a polymerizable compound serving as a binder.

As the polymerizable compound, an appropriate polymerizable compound may be selected from commercially available products or products synthesized by known methods, in consideration of the refractive index of a material forming a wavelength conversion layer to satisfy n1<n2, and used.

Preferred examples of the polymerizable compound include a compound having an ethylenically unsaturated bond at at least one of an end or a side chain, and/or a compound having an epoxy group or oxetane group at at least one of an end or a side chain, and in particular, the compound having an ethylenically unsaturated bond at at least one of an end or a side chain is more preferable. Specific examples of the compound having an ethylenically unsaturated bond at at least one of an end or a side chain include a (meth)acrylate-based compound, an acrylamide-based compound, a styrene-based compound, and maleic anhydride, with the (meth)acrylate-based compound being preferable and the acrylate-based compound being more preferable. As the (meth)acrylate-based compound, (meth)acrylate, urethane (meth)acrylate, polyester (meth)acrylate, epoxy (meth)acrylate, or the like is preferable. As the styrene-based compound, styrene, α-methylstyrene, 4-methylstyrene, divinylbenzene, 4-hydroxystyrene, 4-carboxystyrene, or the like is preferable.

Furthermore, it is also preferable that a compound having a fluorene skeleton is used as the acrylate-based compound. Specific examples of such a compound include the compound represented by Formula (2) described in WO2013/047524A1.

In addition, by way of a preferred example of the binder, a binder which has an acryl polymer as a main chain and has at least one of a urethane polymer having an acryloyl group at the end in the side chain or a urethane oligomer having an acryloyl group at the end; has a molecular weight of 10,000 to 3,000,000, and is formed using a graft copolymer having a double bond equivalent of 500 g/mol or more. As such a graft copolymer, commercially available products such as an ultraviolet-curable urethaneacryl polymer (ACRIT 8BR series) manufactured by TAISEI FINE CHEMICAL CO. LTD. may be used.

In the present invention, the weight-average molecular weight (Mw) of polymers (resins, polymeric materials) may be measured by known methods. By way of an example, the weight-average molecular weight (Mw) may be measured as a molecular weight in terms of polystyrene (PS) by means of gel permeation chromatography (GPC). The weight-average molecular weight of the polymer may use the numeral values described in the catalogues or the like.

The double bond equivalents may also be measured by known methods. Further, the double bond equivalents may also use the numeral values described in the catalogues or the like.

The light diffusion layer 20 is formed by dispersing a light diffusing agent in such a binder.

As the light diffusing agent, a known light diffusing agent (light diffusing particles) can be used as long as it has a different refractive index from that of the binder. Specifically, in a similar manner to the binder, in the light diffusion layer 20, various known light diffusing agents can be used as long as the refractive index n1 of the binder and the refractive index n2 of the light diffusing agent satisfy the relationship of n1>n2.

Accordingly, the light diffusing agents may be either organic particles or inorganic particles, or may be organic and inorganic composite particles. For example, as the organic particles, synthesis resin particles can be used. Specific examples thereof include silicone resin particles, (meth)acrylic resin particles such as polymethyl methacrylate (PMMA), nylon resin particles, styrene resin particles, polyethylene particles, urethane resin particles, and benzoguanamine particles.

From the viewpoint of ready availability of the particles having a suitable refractive index, silicone resin particles and acrylic resin particles are preferable. Among those, from the viewpoint of a low refractive index, good adhesiveness to a graft copolymer which becomes a binder, and the like, silicone resin particles are suitably used.

Furthermore, for the light diffusing agents, particles having a hollow structure can also be used.

As the light diffusing agents, commercially available products can also be suitably used.

Examples thereof include TOSPEARL series of silicone resin particles, manufactured by Momentive Performance Materials Inc.

The particle diameter of the light diffusing agent is not particularly limited, but may be appropriately set, depending on the refractive index of the light diffusing agent, the difference in the refractive indices between the light diffusing agent and the binder, and the like.

According to the studies of the present inventors, the particle diameter of the light diffusing agent is preferably 0.5 μm or more, more preferably 0.5 to 30 μm, and still more preferably 2 to 20 μm.

It is preferable to set the particle diameter of the light diffusing agent to 0.5 μm or more, for example, in views that a good light diffusion effect is obtained.

In addition, the particle diameter of the light diffusing agent may be determined by, for example, an observation using a scanning electron microscope (SEM). Alternatively, as the particle diameter and the refractive index, the numerical values described in the catalogues and the like may be used.

Furthermore, two kinds of light diffusing agents having different particle diameters (sizes) may be used. It is preferable to use two kinds of light diffusing agents having different particle diameters, for example, in views that the brightness of the light irradiated from the quantum dot film can be improved or the distribution of the brightness for the viewing angle when being used in an LCD or the like can be regulated by controlling the ratio of internal scattering to external scattering.

Here, in a case of using two kinds of light diffusing agents having different particle diameters, the particle diameter of the smaller light diffusing agent is preferably 1 to 5 μm, and more preferably 1.5 to 4 μm, from the viewpoint of imparting internal scattering properties. Further, the particle diameter of the larger light diffusing agent is preferably 8 to 15 μm, and more preferably 9 to 12 μm, from the viewpoints of imparting external scattering properties and imparting anti-Newton ring properties.

In the light diffusion layer 20, “the mass of the binder/the mass of the light diffusing agent” which is the ratio of the total mass of the binders to the total mass of the light diffusing agents is preferably 0.1 to 0.8, and more preferably 0.25 to 0.66. That is, in the gas barrier film 10 of the present invention, it is preferable that the light diffusion layer 20 has a higher mass ratio of the light diffusing agent than that of the binder.

It is preferable to set “the mass of the binders/the mass of the light diffusing agents” to 0.1 or more, for example, in views that the strength of the light diffusion layer 20 can be improved and the aggregation peeling of the light diffusion layer 20 can be prevented.

It is preferable to set “the mass of the binders/the mass of the light diffusing agents” to 0.8 or less, for example, in views that good light diffusing performance is obtained.

The thickness of the light diffusion layer 20 may be appropriately set such that desired light diffusing performance, the strength of the light diffusion layer, and the like can be obtained, depending on the kind of the forming materials for the binder or the light diffusing agent.

According to the studies of the present inventors, the thickness of the light diffusion layer 20 is preferably 5 to 25 μm, more preferably 7 to 20 μm, and particularly preferably 9 to 18 μm.

It is preferable to set the thickness of the light diffusion layer 20 to 5 μm or more, for example, in views that good light diffusing performance is obtained.

It is preferable to set the thickness of the light diffusion layer 20 to 25 μm or less, for example, in views that the gas barrier film 10 can be prevented from being unnecessarily thickened, the light diffusion layer 20 having a good light transmittance is obtained, and curling can be suppressed.

As described above, the light diffusion layer 20 is formed by dispersing a light diffusing agent in a binder. Thus, the surface (the surface on the side opposite to the substrate 12) of the light diffusion layer 20 has a certain degree of surface roughness.

According to the present inventors, the surface roughness of the light diffusion layer 20 may be appropriately determined depending on the performance required for the light diffusion layer, a desired adhesion force to the second protective film 28, or the like.

According to the studies of the present inventors, the surface roughness Ra (arithmetic average roughness Ra) of the light diffusion layer 20 is preferably 1 to 7 μm, and more preferably 2 to 5 μm.

It is preferable to set the surface roughness Ra of the light diffusion layer 20 to 1 μm or more, for example, in views that good light diffusing performance is obtained.

It is preferable to set the surface roughness Ra of the light diffusion layer 20 to 7 μm or less, for example, in views that the good adhesion force to the second protective film 28 can be secured, the damages on the inorganic layer 16 due to the transfer of the unevenness of the light diffusion layer 20 at the time of winding the gas barrier film 10 into a roll shape can be prevented, and dependency of viewing angles due to light scattering properties can be controlled.

Furthermore, in the present invention, the surface roughness Ra may be determined in accordance with JIS B 0601 (2001).

It is preferable that the light diffusion layer 20 has a certain degree of hardness. Specifically, it is preferable that the light diffusion layer 20 has a hardness of approximately B to 2H in terms of a pencil hardness.

It is preferable to set the hardness of the light diffusion layer 20 to the above ranges, for example, in views that the light diffusion layer 20 can be reliably prevented from being peeled at the time of peeling the second protective film 28 as will be described later, so as to attain sufficient mechanical strength of the light diffusion layer 20, and the curling of the gas barrier film 10 can be prevented.

The second protective film 28 is provided on the light diffusion layer 20. Further, the position on the light diffusion layer 20 refers to the surface of the light diffusion layer 20, with the surface being on the side opposite to the side of the substrate 12.

In the present invention, the second protective film 28 (diffusion layer-side surface layer) has an adhesive layer 24 provided on the first surface of the support 26. In the second protective film 28, the adhesive layer 24 is provided by being attached to the light diffusion layer 20, and in the same manner as the above-mentioned first protective film 18, the adhesive layer 24 is usually peeled from the light diffusion layer 20. Accordingly, it is preferable that the second protective film 28 has necessary adhesiveness and good peelability, with respect to the light diffusion layer 20.

Such the second protective film 28 protects the inorganic layer 16 from the surface of the substrate 12, with the surface being on the side opposite to the surface on which the inorganic layer 16 or the like is formed.

As described above, the quantum dot is vulnerable to moisture, and therefore, it is thought that in a case where the quantum dot is used as a backlight of an LCD or the like, it is used in the form of a quantum dot film in which a quantum dot layer is sandwiched between gas barrier films. Further, by providing a light diffusion layer on the quantum dot film, the amount of light emitted from the quantum dot layer can be increased.

In a case where the quantum dot layer is sandwiched between the gas barrier films, the inorganic layer 16 expressing gas barrier properties is intended to face the side of the quantum dot layer. Accordingly, the light diffusion layer 20 is formed on the surface of the substrate 12, with the surface being on the side opposite to the surface on which the inorganic layer 16 or the like is formed.

Here, as described above, the light diffusion layer 20 is formed by dispersing a light diffusing agent in a binder, and has a certain degree of surface roughness, that is, surface unevenness. Therefore, in a case where the gas barrier film 10 is subjected to mechanical force such as compression pressure from the outside although the force is indirectly applied, the unevenness of the surface of the light diffusion layer 20 gives a local load on the inorganic layer 16, leading to damages on the inorganic layer 16.

Moreover, the functional film of the present invention, such as the gas barrier film 10, is preferably produced by a so-called roll-to-roll (R-to-R). Further, the functional film of the present invention, such as the gas barrier film 10 produced by R-to-R, is also usually handled by R-to-R.

As is well-known, R-to-R is a production method in which a film-forming material is transferred from a material roll formed by winding a long film-forming material, and subjected to film formation while the film-forming material is transported in the longitudinal direction, and the film-forming material which has been completely subjected to film formation is wound into a roll shape.

When the film having the light diffusion layer 20, such as the gas barrier film 10, is wound, the inorganic layer 16 is subjected to a local load due to the unevenness of the surface of the light diffusion layer 20 from both the surfaces by so-called winding wrinkles, and thus, the inorganic layer 16 is easily damaged.

In addition, although being described later, in the gas barrier film 10, a second functional layer such as an adhesion layer is formed by peeling the first protective film 18. The second functional layer also acts as the protective layer of the inorganic layer 16, but since it has a weaker protective function, as compared with the first protective film 18 having a resin film or the like, damages on the inorganic layer 16 become more significant problems.

In addition, in the gas barrier film for use in a quantum dot film and the like, in order to reduce the thickness of the quantum dot film, a thickness of the substrate 12 is very low, preferably 5 to 100 μm, and more preferably 10 to 50 μm, and as a result, the damages on the inorganic layer 16 due to the unevenness of the light diffusion layer 20 become more significant problems.

In contrast, the gas barrier film 10 of the present invention has a second protective film 28 having the adhesive layer 24 and the support 26 on the light diffusion layer 20.

Therefore, the unevenness of the surface of the light diffusion layer 20 is covered with the second protective film 28 having the adhesive layer 24, and thus, even in a case where the first protective film 18 is peeled, followed by winding into a roll shape, the unevenness of the light diffusion layer 20 remarkably reduces the local load applied to the inorganic layer 16, and thus, damages on the inorganic layer 16 can be prevented.

In addition, as described above, in the gas barrier film for use in a quantum dot film and the like, there are cases where the substrate is thin, the rigidity is weak even in the state where the light diffusion layer 20 is formed, and there is no sufficient handleability with respect to a treatment with R-to-R. In contrast, by allowing the gas barrier film 10 of the present invention to have the second protective film 28, the second protective film 28 also acts as a supplementary support for the gas barrier film 10, and therefore, even in a case where the substrate 12 is thin, good handleability can be secured.

In the gas barrier film 10 of the present invention, as the support 26 of the second protective film 28, various film-shaped materials (sheet-shaped materials) can be used. Specific suitable examples thereof include various resin films exemplified as the substrate 12.

Here, in the gas barrier film 10, it is preferable that the Young's modulus of the first protective film 18 is lower than the Young's modulus of the support 26 of the second protective film 28. Further, in a case where the first protective film 18 is constituted with a resin film and the like together with an adhesive layer, it is preferable that the Young's modulus of the resin film and the like of the first protective film 18 is lower than the Young's modulus of the support 26.

It is preferable to set the Young's modulus of the first protective film 18 to lower than the Young's modulus of the support 26, for example, in views that the stress applied to the inorganic layer 16 can be reduced and the damages on the inorganic layer 16 can be prevented at the time of applying the first protective film 18 or peeling the first protective film 18.

The thickness of the support 26 may be appropriately determined, depending on the forming material for the support 26, the rigidity required for the support 26, or the like.

According to the studies of the present inventors, the thickness of the support 26 is preferably 20 to 100 μm, and more preferably 20 to 70 μm.

It is preferable to set the thickness of the support 26 to 20 μm or more, for example, in views that the inorganic layer 16 can be more reliably protected, winding into a roll shape can be properly carried out while preventing the curling of the second protective film 28, and the mechanical strength can be imparted at the time of peeling the first protective film 18.

It is preferable to set the thickness of the support 26 to 100 82 m or less, for example, in views that the gas barrier film 10 can be prevented from being unnecessarily thickened, the gas barrier film 10 having good flexibility is obtained, the thickness of the gas barrier film 10 can further be reduced, the diameter at the time of winding the gas barrier film 10 into a roll shape can further be reduced, and the thickness or weight of a device in a case where the device is used in the product can further be reduced.

The adhesive layer 24 is not particularly limited, and for example, various adhesive layers formed of known adhesives for use in various adhesive films can be used. Specifically, various adhesive layers using known adhesive materials such as an ethylene-vinyl acetate copolymer-based adhesive material, a polyolefin-based adhesive material, an acrylic adhesive material, a rubber-based adhesive material, a urethane-based adhesive material, a silicone-based adhesive material, and an ultraviolet-curable adhesive material can be used.

The thickness of the adhesive layer 24 may be appropriately determined, depending on the forming material for the adhesive layer 24, the adhesion force required for the second protective film 28, the protection performance of the inorganic layer 16, or the like.

According to the studies of the present inventors, the thickness of the adhesive layer 24 is preferably 1 to 25 μm, and more preferably 10 to 25 μm.

It is preferable to set the thickness of the adhesive layer 24 to 1 μm or more, for example, in views that the surface unevenness of the light diffusion layer 20 can be suitably embedded in the adhesive layer 24, and the damages on the inorganic layer 16 can be more reliably prevented.

It is preferable to set the thickness of the adhesive layer 24 to 25 μm or less, for example, in views that the gas barrier film 10 can be prevented from being unnecessarily thickened, the gas barrier film 10 having good flexibility is obtained, the weight of the gas barrier film 10 can further be reduced, and the diameter at the time of winding the gas barrier film 10 into a roll shape can further be reduced.

Here, it is preferable that the thickness of the adhesive layer 24 is larger than the surface roughness Ra of the light diffusion layer 20.

It is preferable to have such a configuration, for example, in views that the protection ability of the inorganic layer 16 can be improved by suitably embedding the surface unevenness of the light diffusion layer 20 in the adhesive layer 24, and preferred adhesion force is obtained by allowing the adhesive layer 24 to follow the surface unevenness of the light diffusion layer 20.

The second protective film 28 preferably has an average value of the total light transmittance (a wavelength of 400 to 800 nm) of 85% or more.

Although being described later in detail, the gas barrier film 10 is used to prevent the quantum dots from being deteriorated due to moisture by sandwiching a quantum dot layer between the quantum dot films. Here, the quantum dot layer is usually formed by curing the binder by irradiation with ultraviolet rays from the side of the light diffusion layer 20. Accordingly, in a case where the ultraviolet transmittance of the second protective film 28 is low, there are cases where the quantum dot layer cannot be sufficiently cured.

In contrast, by setting the average value of the total light transmittance of the second protective film 28 to 85% or more in the production of a quantum dot film, it is possible to produce a proper quantum dot film stably by reliably curing the quantum dot layer.

Moreover, it is preferable that the second protective film 28 has a dynamic frictional force at the time of bringing the support 26 into contact between the second protective films 28 is 1.5 N/20 mm or less.

Formation of the quantum dot layer or formation of the second functional layer such as an adhesion layer is preferably carried out by a coating method while the first protective film 18 is peeled and the gas barrier film 10 is transported in the longitudinal direction. Further, this formation is preferably carried out by R-to-R. Here, by increasing the sliding properties of the second protective film 28 as described above, damages on the inorganic layer 16 due to generation of wrinkles or the like in the gas barrier film 10 during the transport of the gas barrier film 10 from which the first protective film 18 has been peeled can be suitably prevented.

The adhesion force between the second protective film 28 and the light diffusion layer 20 can be appropriately set to an adhesion force which can allow the second protective film 28 to adhere with a sufficient adhesion force, depending on the binder or the like of the light diffusion layer 20 as well as to be favorably peeled.

According to the studies of the present inventors, the adhesion force between the second protective film 28 and the light diffusion layer 20 is preferably 0.1 to 1 N/25 mm, and more preferably 0.5 to 1 N/25 mm.

It is preferable to set the adhesion force between the second protective film 28 and the light diffusion layer 20 to 0.1 N/25 mm or more, for examples, in views that the second protective film 28 and the light diffusion layer 20 reliably adhere to each other, and thus, damages on the inorganic layer 16 can be suitably prevented, and generation of wrinkles of the second protective film 28 at the time of peeling the first protective film 18 can be prevented.

It is preferable to set the adhesion force between the second protective film 28 and the light diffusion layer 20 to 1 N/25 mm or less, for examples, in views that the peelability of the second protective film 28 can be secured, application of an excess load onto the inorganic layer 16 at the time of peeling the second protective film 28 can be prevented, and the light diffusion layer 20 can be prevented from being peeled or the layers can be prevented from being peeled from each other at the time of peeling the second protective film 28.

In the gas barrier film 10 of the present invention, in order to more reliably prevent damages on the inorganic layer 16, it is preferable to reliably attach the second protective film 28 to the surface of the light diffusion layer 20 and maintain the attachment state while securing good peelability of the second protective film 28.

Here, the attachment strength between the second protective film 28 and the light diffusion layer 20 is affected by the surface roughness of the light diffusion layer 20, the thickness of the adhesive layer 24, and the adhesion force between the second protective film 28 and the light diffusion layer 20.

That is, in a case where the adhesive layer 24 is thin, it is difficult for the adhesive layer 24 to follow the unevenness of the surface of the light diffusion layer 20. Accordingly, in this case, in order to reliably attach the second protective film 28 to the surface of the light diffusion layer 20 and maintain the attachment, it is necessary to increase the adhesion force between the second protective film 28 and the light diffusion layer 20. Conversely, in a case where the adhesive layer 24 has a thickness such that it can sufficiently follow the surface unevenness, the adhesion force between the second protective film 28 and the light diffusion layer 20 may be small.

In addition, in a case where the surface roughness of the light diffusion layer 20 is small, the thickness of the adhesive layer 24 can be reduced and/or the adhesion force between the second protective film 28 and the light diffusion layer 20 can be decreased. Conversely, in a case where the surface roughness of the light diffusion layer 20 is large, the adhesive layer 24 can be thick and/or the adhesion force between the second protective film 28 and the light diffusion layer 20 can be increased.

Taking the above-mentioned points into consideration, the adhesion coefficient of the gas barrier film 10 of the present invention, represented by the following equation, is preferably 0.01 to 25, and more preferably 1 to 7.

Adhesion Coefficient=(Adhesion Force [N/25 mm]×Thickness [μm] of Adhesive Layer)/Ra [μm] of Diffusion Layer

Incidentally, the adhesion force in the above equation is the adhesion force between the second protective film 28 and the light diffusion layer 20. Further, the Ra of the diffusion layer is the surface roughness Ra of the light diffusion layer 20.

It is preferable to set the adhesion coefficient to 0.01 or more, for examples, in views that the inorganic layer 16 can be reliably protected while reliably keeping the attachment state of the second protective film 28.

It is preferable to set the adhesion coefficient to 25 or less, for examples, in views that the second protective film 28 can be easily and suitably peeled.

FIG. 2 conceptually shows an example in which a second aspect of the functional film of the present invention is used in a gas barrier film.

Incidentally, the gas barrier film 30 shown in FIG. 2 has many of the same members as those of the gas barrier film 10 shown in FIG. 1, with the same reference numerals being given to the same members, and the following description mainly has different portions.

The gas barrier film 30 shown in FIG. 2 has an adhesion layer 32 as the second functional layer, instead of the first protective film 18 of the gas barrier film 10 shown in FIG. 1.

That is, by way of an example, the gas barrier film 30 is manufactured by peeling the first protective film 18 from the first gas barrier film 10 shown in FIG. 1, which is the functional film in a first aspect of the present invention, and forming an adhesion layer 32 on the inorganic layer 16.

The adhesion layer 32 is intended to obtain sufficient adhesiveness between the gas barrier film 30 and a laminate body on which the gas barrier film 30 is laminated, in a case where the gas barrier film 30 is attached onto various members or devices, and then used. For example, in a case of using the gas barrier film 30 in a quantum dot film, the adhesion layer 32 is intended to obtain sufficient adhesiveness between the gas barrier film 30 and a binder for forming a quantum dot layer.

As the adhesion layer 32, various adhesive layers with which sufficient adhesion force between the gas barrier film 30 and a member onto which the inorganic layer 16 is attached is obtained can be used, depending on the applications of the gas barrier film 30. For example, in a case of using the gas barrier film 30 in a quantum dot film, a material with which sufficient adhesiveness between the gas barrier film 30 and a binder for forming a quantum dot layer can be obtained may be used.

Examples of the adhesion layer 32 include a layer formed of acrylate monomers or polymers containing a silane coupling agent, and a layer formed of acrylate polymers having an unreacted, radically polymerizable group, urethaneacryl polymers, and acrylic acid monomers or polymers having OH groups even after film hardening, and the like.

Preferred examples of the adhesion layer 32 include an adhesion layer 32 formed using an ultraviolet-curable urethane polymer having a weight-average molecular weight of 5,000 to 30,000 and a double bond equivalent of 300 g/mol or more, which has a urethane polymer as the main chain and a side chain having a (meth)acryloyl group at the end. In the following description, the “ultraviolet-curable urethane polymer having a weight-average molecular weight of 5,000 to 30,000 and a double bond equivalent of 300 g/mol or more” is also simply referred to as an “ultraviolet-curable urethane polymer”.

In addition, in a case where the adhesion layer 32 is formed using the ultraviolet-curable urethane polymer, it is preferable that an adhesion layer is formed using a curable urethane polyester, and a phosphoric acid compound containing two or less (meth)acryloyl groups and/or a silane coupling agent containing one (meth)acryloyl group.

As the ultraviolet-curable urethane polymer, various known ones can be used. Further, commercially available products such as Ultraviolet-Curable Urethane Polymer (ACRIT 8UH series) manufactured by Taisei Fine Chemical Co., Ltd. may be used.

As the curable urethane polyester, various known ones can be used. Further, commercially available products such as VYLON UR series such as VYLON UR1400 manufactured by Toyobo Co., Ltd., may be used.

As the phosphoric acid compound containing two or less (meth)acryloyl groups, various known ones such as bis[2-(methacryloyloxy)ethyl] can be used. Further, commercially available products commercially available compounds such as KAYAMER series manufactured by Nippon Kayaku Co., Ltd. and PHOSMER series manufactured by Uni-Chemical Co., Ltd. may be used.

In addition, as the silane coupling agent containing one (meth)acryloyl group, various known ones such as 3-acryloxypropyl trimethoxysilane can be used. Further, commercially available products such as KBM-5103, KBM-502, KBM-503, KBE-502, KBE-503, and the like manufactured by Shin-Etsu Silicone Co., Inc. may be used.

The thickness of the adhesion layer 32 may be appropriately set, depending on the forming materials of the adhesion layer 32, the thickness or size of the gas barrier film 30, the applications of the gas barrier film, or the like.

According to the studies of the present inventors, the thickness of the adhesion layer 32 is preferably 10 to 1,000 nm, more preferably 50 to 700 nm, and particularly preferably 70 to 500 nm.

It is preferable to set the thickness of the adhesion layer 32 to 10 nm or more, for example, in views that the inorganic layer 16 can be suitably protected.

It is preferable to set the thickness of the adhesion layer 32 to 1,000 nm or less, for example, in views that the gas barrier film 10 can be prevented from being unnecessarily thickened and a low internal stress is maintained to realize high adhesiveness.

Furthermore, in the functional film of the present invention, the second functional layer is not limited to the adhesion layer.

Specific examples of the second functional layer include a wavelength conversion layer, the light extraction layer, an organic electroluminescent layer (organic EL layer), and a conductive layer.

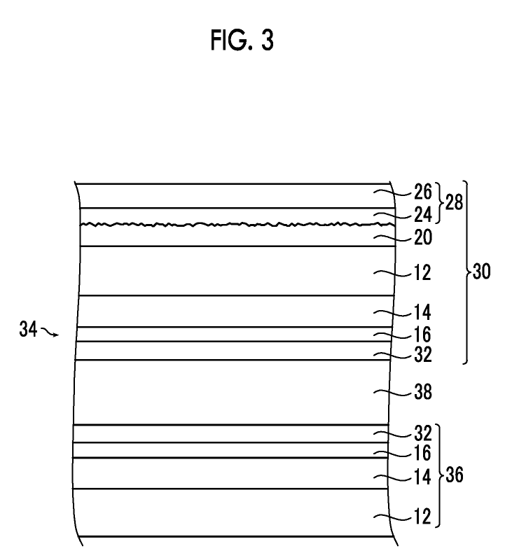

FIG. 3 conceptually shows an example in which a third aspect of the functional film of the present invention is used in a quantum dot film.

Incidentally, the quantum dot film 34 shown in FIG. 3 has many of the same members as those of the gas barrier film 10 shown in FIG. 1 and the gas barrier film 30 shown in FIG. 2, with the same reference numerals being given to the same members, and the following description mainly has different portions.

The quantum dot film 34 is formed by sandwiching the quantum dot layer 38 between the gas barrier film 30 shown in FIG. 2 which is the above-mentioned functional film in the second aspect of the present invention and the gas barrier film 36.

The gas barrier film 36 basically has the same configuration as the gas barrier film 30 except that it does not include the light diffusion layer 20.

The quantum dot film 34 is configured by sandwiching the quantum dot layer 38 between the gas barrier film 30 and the gas barrier film 36 while the adhesion layer 32 is arranged to face the quantum dot layer 38.

Furthermore, in a preferred aspect of the quantum dot film 34 shown in FIG. 3, the quantum dot layer 38 is sandwiched between the gas barrier film 30 and the gas barrier film 36 both having the adhesion layer 32, but the present invention is not limited thereto.

That is, the quantum dot layer 38 may be sandwiched between two gas barrier films having no adhesion layer 32, while the inorganic layer 16 and the quantum dot layer 38 are arranged to face each other. Alternatively, the quantum dot layer 38 may be sandwiched between a gas barrier film having the adhesion layer 32 and a gas barrier film having no adhesion layer 32, while the inorganic layer 16 and the adhesion layer 32 are arranged to face the quantum dot layer 38.

The quantum dot layer 38 is formed by dispersing quantum dots in a binder (matrix) such as a resin. The quantum dot layer 38 has a function of converting the wavelength of the incidence ray to emit the light.

For example, in a case where blue light emitted from a backlight not shown is incident on the quantum dot layer 38, the quantum dot layer 38 converts the wavelength of at least a part of the blue light into red light or green light by the effect of the quantum dot contained inside to emit the light.

The blue light is light having a central light emission wavelength in a wavelength range of 400 nm to 500 nm, the green light is light having a central light emission wavelength in a wavelength range of 500 nm to 600 nm, and the red light is light having a central light emission wavelength in a wavelength range of more than 600 nm to 680 mn or less.

In addition, the function of the wavelength conversion expressed by the quantum dot layer is not limited to a configuration for the wavelength conversion from blue light to red light or green light, and may be any of functions that convert at least a part of incidence ray into light having a different wavelength.

The quantum dot is at least excited by incident excitation light to emit fluorescent light.

The type of the quantum dot contained in the quantum dot layer is not particularly limited and various known quantum dots may be appropriately selected, depending on desired performance of wavelength conversion, and the like.

With regard to the quantum dots (quantum dot materials), reference can be made to, for example, paragraph Nos. [0060] to [0066] of JP2012-169271A, but the quantum dots are not limited thereto. Further, as the quantum dot, a commercialized product can be used without any limitation. The light emission wavelength of the quantum dots can be typically adjusted by the composition or the size of the particle.

The quantum dots may be used singly or in combination of two or more kinds thereof. In a case of using the quantum dots in combination of two or more kinds thereof, two or more kinds of quantum dots having different wavelengths of the emitted light may be used.

Specifically, examples of known quantum dots include a quantum dot (A) having a central light emission wavelength in the wavelength range in a range of 600 nm to 680 nm, a quantum dot (B) having a central light emission wavelength in the wavelength range in a range of 500 nm to 600 nm, and a quantum dot (C) having a central light emission wavelength in the wavelength range in a range of 400 nm to 500 nm, and the quantum dot (A) is excited by excitation light to emit red light, the quantum dot (B) is excited by excitation light to emit green light and the quantum dot (C) is excited by excitation light to emit blue light. For example, when blue light is incident as excitation light on a quantum dot-containing laminate including the quantum dot (A) and the quantum dot (B), red light emitted from the quantum dot (A), green light emitted from the quantum dot (B) and blue light penetrating through the quantum dot layer can realize white light. Alternatively, ultraviolet light can be incident as excitation light on a quantum dot layer including the quantum dots (A), (B), and (C), thereby making it possible to realize white light with red light emitted from the quantum dot (A), green light emitted from the quantum dot (B) and blue light emitted from the quantum dot (C).

Moreover, as the quantum dot, a so-called quantum rod which emits polarized light with directivity in a rod shape may be used.

The quantum dots are preferably dispersed uniformly in the binder, but may be unevenly dispersed in the binder.

The type of the binder of the quantum dot layer 38 is not particularly limited, but various resins that are used as known quantum dot layers can be used.

Examples thereof include polyester-based resins (for example, polyethylene terephthalate and polyethylene naphthalate), (meth)acrylic resins, polyvinyl chloride-based resins, and polyvinyl chloride-based resins.

Alternatively, as the binder, those formed by curing (polymerizing, crosslinking) a curable compound (polymerizable compound (polymerizable monomer)) having one or more polymerizable groups (crosslinkable groups) can be used. In addition, the polymerizable groups of the curable compound substances having two or more polymerizable groups may be the same as or different from each other.

The type of the polymerizable group is not particularly limited, but the polymerizable group is preferably a (meth)acryloyl group, a vinyl group, or an epoxy group, more preferably a (meth)acryloyl group, and still more preferably an acryloyl group. That is, in the present invention, the binder of the quantum dot layer is preferably a (meth)acrylic resin, and more preferably an acrylic resin.

In the quantum dot layer 38, specifically, for example, a resin formed by curing a curable composition including a first curable compound and a second curable compound, which will be described below, can be used as the binder.

The first curable compound is preferably one or more compounds selected from bifunctional or higher (meth)acrylate monomers and monomers having two or more functional groups selected from the group consisting of an epoxy group and an oxetanyl group.

Preferred examples of the bifunctional (meth)acrylate monomers among the bifunctional or higher (meth)acrylate monomers include neopentyl glycol di(meth)acrylate, 1,9-nonanediol di(meth)acrylate, tripropylene glycol di(meth)acrylate, ethylene glycol di(meth)acrylate, tetraethylene glycol di(meth)acrylate, hydroxypivalic acid neopentyl glycol di(meth)acrylate, polyethylene glycol di(meth)acrylate, dicyclopentenyl (meth)acrylate, dicyclopentenyloxyethyl (meth)acrylate, and dicyclopentanyl di(meth)acrylate.

Furthermore, preferred examples of the trifunctional or higher (meth)acrylate monomers among the bifunctional or higher (meth)acrylate monomers include ECH-modified glycerol tri(meth)acrylate, EO-modified glycerol tri(meth)acrylate, PO-modified glycerol tri(meth)acrylate, pentaerythritol triacrylate, pentaerythritol tetraacrylate, EO-modified phosphoric acid triacrylate, trimethylolpropane tri(meth)acrylate, caprolactone-modified trimethylolpropane tri(meth)acrylate, EO-modified trimethylolpropane tri(meth)acrylate, PO-modified trimethylolpropane tri(meth)acrylate, tris(acryloxyethyl)isocyanurate, dipentaerythritol hexa(meth)acrylate, dipentaerythritol penta(meth)acrylate, caprolactone-modified dipentaerythritol hexa(meth)acrylate, dipentaerythritol hydroxypenta(meth)acrylate, alkyl-modified dipentaerythritol penta(meth)acrylate, dipentaerythritol poly(meth)acrylate, alkyl-modified dipentaerythritol tri(meth)acrylate, ditrimethylolpropane tetra(meth)acrylate, pentaerythritolethoxy tetra(meth)acrylate, and pentaerythritol tetra(meth)acrylate.

As the monomer having two or more functional groups selected from the group consisting of an epoxy group and an oxetanyl group, for example, aliphatic cyclic epoxy compound, bisphenol A diglycidyl ether, bisphenol F diglycidyl ether, bisphenol S diglycidyl ether, brominated bisphenol A diglycidyl ether, brominated bisphenol F diglycidyl ether, brominated bisphenol S diglycidyl ether, hydrogenated bisphenol A diglycidyl ether, hydrogenated bisphenol F diglycidyl ether, hydrogenated bisphenol S diglycidyl ether, 1,4-butanediol diglycidyl ether, 1,6-hexanediol diglycidyl ether, glycerin triglycidyl ether, trimethylolpropane triglycidyl ether, polyethylene glycol diglycidyl ether, and polypropylene glycol diglycidyl ethers; polyglycidyl ethers of polyetherpolyols obtained by adding one kind or two or more kinds of alkylene oxides to aliphatic polyhydric alcohols such as ethylene glycol, propylene glycol, and glycerin; diglycidyl esters of aliphatic long-chain dibasic acids; glycidyl esters of higher fatty acids; and compounds including epoxycycloalkane are suitably used.

Examples of commercially available products which can suitably be used as the monomer having two or more functional groups selected from the group consisting of an epoxy group and an oxetanyl group include CELLOXIDE 2021P and CELLOXIDE 8000, both manufactured by Daicel Corporation, and 4-Vinylcyclohexene Dioxide manufactured by Sigma Aldrich. These can be used singly or in combination of two or more kinds thereof.

Furthermore, a method for producing the monomer having two or more functional groups selected from the group consisting of an epoxy group and an oxetanyl group is not limited, but can be synthesized with reference to, for example, 20 Organic Synthesis II in Experimental Chemistry Series 4^{th} ed., 213 to, 1992, Japan Chemical Society Ed., Maruzen Publ. Co., Ed. by Alfred Hasfner, The chemistry of heterocyclic compounds-Small Ring Heterocycles part3 Oxiranes, John & Wiley and Sons, An Interscience Publication, New York, 1985, Yosimura, Adhesion, Vol. 29, No. 12, 32, 1985, Yoshimura, Adhesion, Vol. 30, No. 5, 42, 1986, Yoshimura, Adhesion, Vol. 30, No. 7, 42, 1986, JP1999-100378A (JP-H11-100378A), JP2906245B, JP2926262B, and the like.

The second curable compound has a functional group having hydrogen bonding properties in the molecule, and a polymerizable group capable of performing a polymerization reaction with the first curable compound.

Examples of the functional group having hydrogen bonding properties in the molecule include a urethane group, a urea group, and a hydroxyl group.

The polymerizable group capable of performing a polymerization reaction with the first curable compound may be, for example, a (meth)acryloyl group when the first curable compound is a bifunctional or higher (meth)acrylate monomer, or the polymerizable group may also be an epoxy group or an oxetanyl group when the first curable compound is the monomer having two or more functional groups selected from the group consisting of an epoxy group and an oxetanyl group.

The (meth)acrylate monomer containing a urethane group is a monomer or oligomer obtained by reacting a diisocyanate such as TDI, MDI, HDI, IPDI, and HMDI with a polyol such as poly(propylene oxide)diol, poly(tetramethylene oxide)diol, ethoxylated bisphenol A, ethoxylated bisphenol S spiroglycol, caprolactone-modified diol, and carbonate diol, and a hydroxyacrylate such as 2-hydroxyethyl (meth)acrylate, 2-hydroxypropyl (meth)acrylate, glycidol di(meth)acrylate, and pentaerythritol triacrylate, and examples thereof include polyfunctional urethane monomers described in JP2002-265650A, JP2002-355936A, JP2002-067238A, and the like. Specific examples of the urethane acrylate include, but are not limited to, an adduct of TDI and hydroxyethyl acrylate, an adduct of IPDI and hydroxyethyl acrylate, an adduct of HDI and pentaerythritol triacrylate (PETA), a compound obtained by preparing an adduct of TDI and PETA and reacting the remaining isocyanate with dodecyloxyhydroxypropyl acrylate, an adduct of 6,6-nylon and TDI, and an adduct of pentaerythritol, TDI, and hydroxyethyl acrylate.

Examples of the commercially available products which can suitably be used as the (meth)acrylate monomer containing a urethane group include AH-600, AT-600, UA-306H, UA-306T, UA-3061, UA-510H, UF-8001G, and DAUA-167, all manufactured by Kyoeisha Chemical Co., Ltd., UA-160TM manufactured by Shin-Nakamura Chemical Co., Ltd., and UV-4107F and UV-4117F, both manufactured by Osaka Organic Chemical Industry Ltd. These can be used singly or in combination of two or more kinds thereof.

Examples of the (meth)acrylate monomer containing a hydroxyl group include compounds synthesized by the reaction of a compound having an epoxy group with a (meth)acrylic acid. Typically, the compounds are classified into ones of a bisphenol A type, a bisphenol S type, a bisphenol F type, an epoxidized oil type, a novolac type of phenol, and an alicyclic type phenol for the compounds having an epoxy group. Specific examples thereof include, but not limited to, a (meth)acrylate obtained by reacting an adduct of bisphenol A and epichlorohydrin with (meth)acrylic acid, a (meth)acrylate obtained by reacting phenol novolac with epichlorohydrin, and then with (meth)acrylic acid, a (meth)acrylate obtained by reacting an adduct of bisphenol S and epichlorohydrin with (meth)acrylic acid, and a (meth)acrylate obtained by reacting an epoxidized soy bean oil with (meth)acrylic acid. In addition, other examples of the (meth)acrylate monomer containing a hydroxyl group include (meth)acrylate monomers having a carboxyl group or a phosphoric acid group at an end.

Examples of the commercially available products which can suitably be used as the second curable compound containing a hydroxyl group include Epoxy Ester, M-600A, 40EM, 70PA, 200PA, 80MFA, 3002M, 3002A, 3000MK, and 3000A, all manufactured by Kyoeisha Chemical Co., Ltd., 4-Hydroxybutyl Acrylate manufactured by Nippon Kasei Chemical Co., Ltd., Monofunctional Acrylate A-SA and Monofunctional Methacrylate SA, both manufactured by Shin-Nakamura Chemical Co., Ltd., Monofunctional Acrylate β-Carboxyethyl Acrylate manufactured by Daicel-Allnex Ltd., and JPA-514 manufactured by Johoku Chemical Co, Ltd. These can be used singly or in combination of two or more kinds thereof.

The mass ratio of the first curable compound to the second curable compound is any ratio from 10:90 to 99:1, and is preferably 10:90 to 90:10. It is preferable that the content of the first curable compound is larger than that of the second curable compound, and specifically, the ratio of (the content of the first curable compound)/(the content of the second curable compound) is preferably 2 to 10.

In a case of using a resin formed by curing the first curable compound and the second curable compound as the binder, it is preferable that a monofunctional (meth)acrylate monomer is further included as the curable composition. Examples of the monofunctional (meth)acrylate monomer include acrylic acids and methacrylic acids, and derivatives thereof, and more specifically monomers having one polymerizable unsaturated bond ((meth)acryloyl groups) of a (meth)acrylic acid in the molecule. Specific examples thereof include the following compounds, but the present invention is not limited thereto:

alkyl (meth)acrylates with an alkyl group having 1 to 30 carbon atoms, such as methyl (meth)acrylate, n-butyl (meth)acrylate, isobutyl (meth)acrylate, 2-ethylhexyl (meth)acrylate, isononyl (meth)acrylate, n-octyl (meth)acrylate, lauryl (meth)acrylate, and stearyl (meth)acrylate; arylalkyl (meth)acrylates with an arylalkyl group having 7 to 20 carbon atoms, such as benzyl (meth)acrylate; alkoxyalkyl (meth)acrylates with an alkoxyalkyl group having 2 to 30 carbon atoms, such as butoxyethyl (meth)acrylate; aminoalkyl (meth)acrylate with a (mono-alkyl or di-alkyl) aminoalkyl group having 1 to 20 carbon atoms in total, such as N,N-dimethylaminoethyl (meth)acrylate; (meth)acrylates of polyalkylene glycol alkyl ether with an alkylene chain having 1 to 10 carbon atoms and an end alkyl ether having 1 to 10 carbon atoms, such as (meth)acrylate of diethylene glycol ethyl ether, (meth)acrylate of triethylene glycol butyl ether, (meth)acrylate of tetraethylene glycol monomethyl ether, (meth)acrylate of hexaethylene glycol monomethyl ether, monomethyl ether (meth)acrylate of octaethylene glycol, monomethyl ether (meth)acrylate of nonaethylene glycol, monomethyl ether (meth)acrylate of dipropylene glycol, monomethyl ether (meth)acrylate of heptapropylene glycol, and monoethyl ether (meth)acrylate of tetraethylene glycol; (meth)acrylates of polyalkylene glycol aryl ether with an alkylene chain having 1 to 30 carbon atoms and an end aryl ether having 6 to 20 carbon atoms, such as (meth)acrylate of hexaethylene glycol phenyl ether; (meth)acrylate having 4 to 30 carbon atoms in total, having an alicyclic structure, such as cyclohexyl (meth)acrylate, dicyclopentanyl (meth)acrylate, isobornyl (meth)acrylate, and methylene oxide adduct cyclodecatriene (meth)acrylate; fluorinated alkyl (meth)acrylates having 4 to 30 carbon atoms in total, such as heptadecafluorodecyl (meth)acrylate; (meth)acrylates having a hydroxyl group, such as 2-hydroxyethyl (meth)acrylate, 3-hydroxypropyl (meth)acrylate, 4-hydroxybutyl (meth)acrylate, mono(meth)acrylate of triethylene glycol, tetraethylene glycol mono(meth)acrylate, hexaethylene glycol mono(meth)acrylate, octapropylene glycol mono(meth)acryl ate, and mono- or di-(meth)acrylate of glycerol; (meth)acrylates having a glycidyl group such as glycidyl (meth)acrylate; polyethylene glycol mono(meth)acrylates with an alkylene chain having 1 to 30 carbon atoms such as tetraethylene glycol mono(meth)acrylate, hexaethylene glycol mono(meth)acryl ate, and octapropylene glycol mono(meth)acrylate; and (meth)acrylamides such as (meth)acrylamide, N,N-dimethyl (meth)acrylamide, N-isopropyl (meth)acrylamide, 2-hydroxyethyl (meth)acryl amide, and acryloylmorpholine.

The monofunctional (meth)acrylate monomers are included in an amount of preferably 1 to 300 parts by mass, and more preferably 50 to 150 parts by mass, with respect to 100 parts by mass of the total mass of the first curable compound and the second curable compound.

Moreover, compounds containing a long-chain alkyl group having 4 to 30 carbon atoms are preferably included. Specifically, it is preferable that at least one of the first curable compound, the second curable compound, or the monofunctional (meth)acrylate monomer contains a long-chain alkyl group having 4 to 30 carbon atoms. The long-chain alkyl group is more preferably a long-chain alkyl group having 12 to 22 carbon atoms since the dispersibility of quantum dots is improved. The more the dispersibility of quantum dots is enhanced, the more the amount of light advancing directly from the light wavelength conversion layer to the light emission surface is increased, which is effective for improving a front brightness and a front contrast.

Specifically, as the monofunctional (meth)acrylate monomer containing a long-chain alkyl group having 4 to 30 carbon atoms, butyl (meth)acrylate, octyl (meth)acrylate, lauryl (meth)acrylate, oleyl (meth)acrylate, stearyl (meth)acrylate, behenyl (meth)acrylate, butyl (meth)acrylamide, octyl (meth)acrylamide, lauryl (meth)acryl amide, oleyl (meth)acrylamide, stearyl (meth)acrylamide, behenyl (meth)acrylamide, and the like are preferable. Among these, lauryl (meth)acrylate, oleyl (meth)acrylate, and stearyl (meth)acrylate are particularly preferable.

Furthermore, a compound having a fluorine atom, such as trifluoroethyl (meth)acrylate, pentafluoroethyl (meth)acrylate, (perfluorobutyl)ethyl (meth)acrylate, perfluorobutyl-hydroxypropyl (meth)acrylate, (perfluorohexyl)ethyl (meth)acrylate, octafluoropentyl (meth)acrylate, perfluorooctylethyl (meth)acrylate, and tetrafluoropropyl (meth)acrylate, may be included as the curable compound. By incorporation of these compounds, the coatability can be improved.

In the quantum dot layer 38, the amount of the binder is not particularly limited, and but may be appropriately set, depending on the type of the curable compound to be used, the thickness of the quantum dot layer 38, and the like.

According to the studies of the present inventors, the amount of the binder is preferably 90 to 99.9 parts by mass, and more preferably 92 to 99 parts by mass, with respect to 100 parts by mass of the total amount of the quantum dot layer 38.

The thickness of the quantum dot layer 38 is not particularly limited, but is preferably 5 to 200 μm, and more preferably 10 to 150 μm.

It is preferable to set the thickness of the quantum dot layer 38 to 5 μm or more, for example, in views that good light emitting characteristics are obtained.

It is preferable to set the thickness of the quantum dot layer 38 to 200 μm or less, for example, in views that the quantum dot film 34 can be prevented from being unnecessarily thick, the quantum dot film 34 having good handleability is obtained, and the quantum dot layer 38 having no aggregation peeling can be formed.

Hereinafter, the production methods of the present invention will be described by describing the methods for producing the gas barrier film 10, the gas barrier film 30, and the quantum dot film 34.

In addition, formation of the respective layers, the attachment of the films, and the like in the following production methods are all preferably carried out by R-to-R, using a long substrate 12, a support 26, or the like.

By way of an example, the gas barrier film 10 shown in FIG. 1 is manufactured as described below.

First, an organic layer 14 is formed on a substrate 12. The organic layer 14 is formed (film formation) by a known method for forming a layer including an organic compound, depending on the organic layer 14 to be formed. By way of an example, a coating method is exemplified.

That is, the organic layer 14 is formed by preparing a coating composition including an organic solvent, an organic compound (a monomer, a dimer, a trimer, an oligomer, a polymer, and the like) serving as the organic layer 14, a surfactant, a silane coupling agent, and the like, applying the coating composition onto the substrate 12, then drying the coating composition, and polymerizing (crosslinking) the organic compounds by irradiation with ultraviolet rays or the like, as desired.

Furthermore, after forming the organic layer 14, a protective film for protecting the organic layer 14 may be attached onto the surface of the organic layer 14.

Then, an inorganic layer 16 is formed on the organic layer 14.

A film-forming method for the inorganic layer 16 is not limited and various known methods for forming inorganic layers (inorganic films) can be used, depending on the inorganic layer 16 to be formed.

Specifically, the inorganic layer 16 may be formed by vapor-phase film-forming methods including plasma CVDs such as CCP-CVD and ICP-CVD, sputtering such as magnetron sputtering and reactive sputtering, and vacuum vapor deposition.

In addition, in a case where a protective film for protecting the organic layer 14 is attached onto the surface of the organic layer 14, the inorganic layer 16 is formed after peeling the protective film.

In a case of a plurality of combinations of the inorganic layer 16 and the organic layer 14 serving as a base substrate, formation of the organic layer 14 and formation of the inorganic layer 16 are repeatedly carried out, depending on the number of combinations.

When the inorganic layer 16 which is the outermost layer is formed, the first protective film 18 is attached onto the inorganic layer 16.

Here, in a case where the inorganic layer 16 is formed by R-to-R, it is preferable that the first protective film 18 is attached onto the inorganic layer 16 which is the outermost layer, before the formed inorganic layer 16 is brought into contact with other members in the film-forming room in the formation of the inorganic layer 16 which is the outermost layer.

When the first protective film 18 is attached onto the inorganic layer 16 which is the outermost layer, the light diffusion layer 20 is formed on the surface of the substrate 12, with the surface being on the side opposite to the surface on which the organic layer 14 and the inorganic layer 16 are formed.

The light diffusion layer 20 may be formed by a known method for forming a layer including an organic compound, depending on a binder used in the light diffusion layer 20, and the like.

By way of an example, the light diffusion layer 20 may be formed by a coating method. That is, a coating composition including an organic solvent, a compound serving as a binder, and a light diffusing agent is prepared. As desired, a thermal polymerization initiator, a surfactant, a dispersant, or the like may be added to the coating composition. Then, the coating composition is applied onto the substrate 12, and dried, and the binder is cured by light irradiation such as ultraviolet irradiation, heating, or the like to form the light diffusion layer 20.

Regulation of the surface roughness Ra of the light diffusion layer 20 may be carried out by regulation of the amount ratio of the binder to the light diffusing agent in the coating composition, and the like by way of an example.

On the other hand, an adhesive layer 24 is formed on the support 26 to manufacture a second protective film 28.

The second protective film 28 may be manufactured by a known method, depending on the forming material of the adhesive layer 24. By way of an example, a coating method is exemplified.

That is, first, a resin film serving as the support 26, and the like are prepared. On the other hand, a coating composition formed by dispersing or dissolving a compound serving as the adhesive layer 24 in an organic solvent is prepared. As desired, a thermal polymerization initiator, a surfactant, a dispersant, or the like may be added to the coating composition.

Then, the coating composition is applied onto the support 26, and dried, and the compound serving as the adhesive layer 24 is cured by ultraviolet irradiation, heating, or the like to form a second protective film 28.

Regulation of the adhesion force between the second protective film 28 and the light diffusion layer 20 may be carried out by selecting a compound serving as the adhesive layer 24, by way of an example. Further, the adhesion force between the second protective film 28 and the light diffusion layer 20 can be regulated even only by regulating the curing conditions of the compound serving as the adhesive layer 24, such as the irradiation dose of the ultraviolet rays.

In a case where the light diffusion layer 20 is formed and the second protective film 28 is manufactured, the light diffusion layer 20 and the adhesive layer 24 are arranged to face each other, and the second protective film 28 is attached onto the light diffusion layer 20 to manufacture the gas barrier film 10.

In a case where the second protective film 28 is laminated and attached onto the light diffusion layer 20, pressurization or heating may also be used, as desired.

In addition, in a case where the gas barrier film 10 is manufactured by R-to-R, it is preferable that after forming the light diffusion layer 20 and before winding it, the second protective film 28 is laminated and attached onto the light diffusion layer 20 to form the gas barrier film 10, which is then wound, in order to prevent damages on the inorganic layer 16 due to the surface unevenness of the light diffusion layer 20.

The gas barrier film 30 shown in FIG. 2 is manufactured as described below, by way of an example.

First, the first protective film 18 is peeled from the gas barrier film 10 manufactured as described above. Then, the adhesion layer 32 is formed on the surface of the inorganic layer 16, thereby manufacturing the gas barrier film 30.

The adhesion layer 32 may be formed by a known method for forming a layer including an organic compound, depending on the forming material of the adhesion layer 32, or the like.

By way of an example, the adhesion layer 32 may be formed by a coating method. That is, first, a coating composition including an organic solvent and a compound serving as the adhesion layer 32 is prepared. As desired, a thermal polymerization initiator, a surfactant, a dispersant, or the like may be added to the coating composition.

Then, the coating composition is applied onto the surface of the inorganic layer 16, the coating composition is dried, and the compound serving as the adhesion layer 32 is cured by heating, ultraviolet irradiation, or the like, thereby forming an adhesion layer 32 and manufacturing the gas barrier film 30.

The quantum dot film 34 shown in FIG. 3 is manufactured as described below, by way of an example.

The gas barrier film 30 and the gas barrier film 36 manufactured as described above are prepared. The gas barrier film 36 may be manufactured by not forming the light diffusion layer 20 and the second protective film 28 in the manufacture of the gas barrier films 10 and 30.

On the other hand, a coating, composition (polymerizable composition) serving as the quantum dot layer 38 is prepared by dispersing quantum dots in a curable compound serving as a binder. The coating composition may also contain a photopolymerization initiator, a surfactant, or the like, as desired.

When the gas barrier film 30, the gas barrier film 36 and the coating composition serving as the quantum dot layer 38 are prepared, the coating composition serving as the quantum dot layer 38 is applied onto the adhesion layer 32 of the gas barrier film 30.

Then, the gas barrier film 36 is laminated thereonto while the adhesion layer 32 is arranged to face the coating composition.

In this manner, in a case where the coating composition serving as the quantum dot layer 38 is sandwiched between the gas barrier film 30 and the gas barrier film 36 the curable compound serving as a binder in the coating composition is polymerized ultraviolet irradiation, heating, or the like, thereby forming the quantum dot layer 38 and manufacturing the quantum dot film 34.

The gas barrier films 10 and 30, or the quantum dot film 34 of the present invention has the second protective film 28 on the light diffusion layer 20.

As a result, in the gas barrier films 10 and 30, or the quantum dot film 34 of the present invention, damages on the inorganic layer 16, due to the light diffusion layer 20 with the surface unevenness can be prevented even when peeling of the first protective film 18, formation of the adhesion layer 32, formation of the quantum dot layer 38, and the like are carried out by R-to-R, and when operations, treatments, and the like for their uses in various applications are carried out.

Furthermore, in the above-mentioned examples, the quantum dot film 34 is manufactured by applying the coating composition serving as the quantum dot layer 38 on the adhesion layer 32 of the gas barrier film 30, laminating the gas barrier film 36 onto the coating composition, and curing the coating composition. However, the present invention is not limited thereto, and the quantum dot film 34 may also be manufactured by applying the coating composition serving as the quantum dot layer 38 onto the adhesion layer 32 of the gas barrier film 36 laminating the gas barrier film 30 onto the coating composition, and curing the coating composition.

In addition, in the quantum dot film 34, it is the same as above that the gas barrier film 30 and/or the gas barrier film 36 does not have the adhesion layer 32. In this case, the first protective film 18 is peeled from the gas barrier film, the inorganic layer 16 and the quantum dot layer 38 are then arranged to face each other while not forming the adhesion layer, and may be used for the manufacture of the quantum dot film in the same manner.

The quantum dot film 34 is suitably used in illumination devices such as a backlight unit in an LCD or the like. Here, the second protective film 28 is finally peeled in a case where the quantum dot film 34 is used.

In addition, the second protective film 28 is finally peeled in a case where the gas barrier films 10 and 30 are used in various applications.

Hereinabove, the functional film and the method for producing a functional film of the present invention are described in detail. However, it is certain that the present invention is not limited to Examples and various modifications or alterations may be made within a range not departing from the gist of the present invention.

### EXAMPLES

Hereinbelow, the present invention will be described in more detail with reference to specific Examples of the present invention.

### Examples 1 to 27]

The gas barrier film 30 was manufactured as follows.

<Formation of Organic Layer 14>

As the substrate 12, a long PET film (COSMO SHINE A4300 manufactured by Toyobo Co., Ltd.) having a width of 1,000 mm and a thickness of 50 82 m was prepared.

In addition, TMPTA (manufactured by Daicel-Cytec Co., Ltd.) and a photopolymerization initiator (ESACURE KTO 46 manufactured by Lamberti S.p.A.) were prepared and weighed such that the mass ratio thereof was 95:5. These were dissolved in methyl ethyl ketone such that the concentration of the solid content was 15% by mass, thereby preparing a coating composition for forming an organic layer 14.

The coating composition for forming an organic layer 14 was charged in a predetermined position of a coating unit of a film-forming device using general R-to-R, including a coating unit using a die coater, a drying unit using warm air, a curing unit using irradiation with ultraviolet rays, and a laminating unit in a long film shape. Further, a roll formed by winding the substrate 12 into a roll shape was loaded in a predetermined position of the film-forming device, and the substrate 12 was inserted through a predetermined transport path. In addition, a roll formed by winding a long protective film into a roll shape was loaded in a predetermined position of the laminating unit, and the protective film was inserted through a predetermined transport path.

Moreover, as the protective film, a LDPE film (SUNYTECT PAC-2 manufactured by Sun A. Kaken Co., Ltd., Young's modulus of 0.3 GPa) having a width of 1,000 mm and a thickness of 30 μm.

In the film-forming device, while transporting the substrate 12 in the longitudinal direction, the coating composition was applied using a die coater, and passed through a drying unit at 50° C. for 3 minutes. Thereafter, the coating composition was cured by irradiation with ultraviolet rays (integrated irradiation dose of about 600 mJ/cm²), and the coating composition was cured to form an organic layer 14. A protective film was attached onto the organic layer 14 and wound into a roll shape. The thickness of the organic layer 14 was 1 μm.

<Formation of Inorganic Layer 16>

The roll of the substrate 12 having the organic layer 14 formed thereon was loaded in a predetermined position of a general CVD film-forming device which performs film formation by CCP-CVD (capacity coupled plasma CVD) using R-to-R, and the substrate 12 and the protective film were inserted through a predetermined transport path. Further, a roll formed by winding the long first protective film 18 into a roll shape was loaded in a predetermined position of the laminating unit, and the first protective film 18 was inserted through a predetermined transport path.

Furthermore, as the first protective film 18, the same protective film as that of the organic layer 14 was used.

In this CVD film-forming device, while the substrate 12 having the organic layer 14 formed thereon was transported in the longitudinal direction, the protective film is peeled, a silicon nitride film as the inorganic layer 16 was then formed on the organic layer 14, and the first protective film 18 was attached onto the inorganic layer 16 and wound into a roll shape.

As raw material gases, a silane gas (a flow rate of 160 sccm), an ammonia gas (a flow rate of 370 sccm), a hydrogen gas (a flow rate of 590 sccm), and a nitrogen gas (a flow rate of 240 sccm) were used. As a power supply, a high-frequency power supply having a frequency of 13.56 MHz was used, and a plasma excitation electric power was set to 800 W. The film-forming pressure was set to 40 Pa. The film thickness of the inorganic layer 16 was 50 nm.

In addition, attachment of the first protective film 18 was carried out after forming the inorganic layer 16 and before bringing the inorganic layer 16 into contact with other members in the film-forming room.

<Manufacture of Second Protective Film 28>

As the support 26, a long PET film (LUMIRROR manufactured by Toray Industries, Inc., a Young's modulus of 4 GPa) having a width of 1,000 mm and a thickness of 50 μm was prepared.

A roll formed by winding the support 26 into a roll shape was loaded in a predetermined position of a film-forming device using general R-to-R, including a coating unit using a die coater and a laminating unit in a long film shape, and the support 26 was inserted through a predetermined transport path. Further, an acrylic resin adhesive (manufactured by PANAC Co., Ltd.) serving as the adhesive layer 24 was charged in a predetermined position of the coating unit. In addition, a roll formed by winding a long release paper into a roll shape was loaded in a predetermined position of the laminating unit, and the release paper was inserted through a predetermined transport path.

In the coating device, while the support 26 was transported in the longitudinal direction, the acrylic resin adhesive was applied by a die coater to form the adhesive layer 24 and manufacture a second protective film 28. Further, the release paper was attached onto the adhesive layer 24 and wound into a roll shape.

<Formation of Light Diffusion Layer 20 and Manufacture of Gas Barrier Film 10>

A binder (ACRIT 8BR-930 manufactured by Taisei Fine Chemical Co. Ltd.), a light diffusing agent 1 (silicone resin particles, TOSPEARL 130 manufactured by Momentive Performance Materials Inc., an average particle diameter of 3.0 μm, and a refractive index of 1.425), a light diffusing agent 2 (silicone resin particles, TOSPEARL 1100 manufactured by Momentive Performance Materials Inc., an average particle diameter of 11.0 μin, and a refractive index of 1.425), and a photopolymerization initiator (IRGACURE 184 manufactured by BASF Corp.) were prepared.

ACRIT 8BR-930 which was used as the binder is a graft copolymer having a weight-average molecular weight of 16,000, a double bond equivalent of 800 g/mol, and a refractive index of 1.4671, which has an acrylic polymer as a main chain and has a urethane polymer with an acryloyl group at an end and a urethane oligomer with an acryloyl group at an end.

These were appropriately weighed at the ratios set, and dissolved in methyl isobutyl ketone such that the concentration of the solid content was 55% by mass, thereby preparing a coating composition for forming a light diffusion layer 20.

The coating composition for forming a light diffusion layer 20 was charged in a predetermined position of a coating unit of a film-forming device using general R-to-R, including a coating unit using a die coater, a drying unit using heating, an irradiation unit using ultraviolet rays, and a peeling unit and a laminating unit in a long film shape. Further, a roll of the substrate 12 having the inorganic layer 16 formed thereon was loaded in a predetermined position of the film-forming device, and the substrate 12 was inserted through a predetermined transport path. In addition, a roll formed by winding a second protective film 28 was loaded in a predetermined position of the laminating unit, and the second protective film 28 and the release film were inserted through a predetermined transport path.

Loading of the roll of the substrate 12 and loading of the second protective film 28 were carried out while the coating composition on the surface of the substrate 12, with the surface being on the side opposite to the surface on which the inorganic layer 16 was formed, and the light diffusion layer 20 and the adhesive layer 24 were arranged to face each other in the lamination position.

In the film-forming device, while transporting the substrate 12 in the longitudinal direction, the coating composition was applied using a die coater, passed through a drying unit at 60° C. for 3 minutes, and irradiated with ultraviolet rays to form a light diffusion layer 20. Further, the release film was peeled from the second protective film 28, and then the substrate 12 and the second protective film 28 were laminated and attached onto each other while the light diffusion layer 20 and the adhesive layer 24 were arranged to face each other, to manufacture a gas barrier film 10, which was wound into a roll shape.

<Manufacture of Gas Barrier Film 30>

An ultraviolet-curable urethane polymer (ACRIT 8UH-1006 manufactured by Taisei Fine Chemical Co., Ltd.), a urethane polyester (VYLON UR1410 manufactured by Toyobo Co., Ltd.), a phosphoric acid compound (bis[2-(methacryloyloxy)ethyl] phosphate manufactured by Sigma Aldrich), and a silane coupling agent (KBM5103 manufactured by Shin-Etsu Silicone Co., Inc.) were weighed such that the mass ratio of the ultraviolet-curable urethane polymer:the urethane polyester:the phosphoric acid compound:the silane coupling agent was 50:15:25:10, and dissolved in methyl ethyl ketone such that the concentration of the solid content was 2% by mass, thereby preparing a coating composition for forming an adhesion layer 32.

Furthermore, ACRIT 8UH-1006 used as the ultraviolet-curable urethane polymer is an ultraviolet-curable urethane polymer having a weight-average molecular weight of 20,000 and a double bond equivalent of 366 g/mol, which has a urethane polymer as the main chain and a side chain having a (meth)acryloyl group at an end.

The coating composition for forming the adhesion layer 32 was charged in a predetermined position of a coating unit of a film-forming device using general R-to-R, including a laminating unit in a long film shape, the coating unit using a die coater, and a drying zone using heating. Further, a roll of the gas barrier film 10 was loaded in a predetermined position of the film-forming device, and the gas barrier film 10 and the first protective film 18 were inserted through a predetermined transport path. In addition, the roll of the gas barrier film 10 was loaded such that the side of the first protective film 18 was peeled and served as a coating surface.

In the film-forming device, while transporting the substrate 12 in the longitudinal direction, the first protective film 18 was peeled from the gas barrier film 10, and thereafter, the coating composition was applied onto the inorganic layer 16, using the die coater, passed through a drying unit at 110° C. for 3 minutes, and wound, thereby forming the adhesion layer 32 and manufacturing the gas barrier film 30.

For such the manufacture of the gas barrier film 30, gas barrier films 30 of Examples 1 to 27 were manufactured by:

changing the surface roughness Ra of the light diffusion layer 20 was to 1 μm, 3.5 μm, and 7 μm,

changing the adhesion force between the second protective film 28 and the light diffusion layer 20 to 0.1 N/25 mm, 0.5 N/25 mm, and 1 N/25 mm, and changing the thickness of the adhesive layer 24 of the second protective film 28 to 1 μm, 10 μm, and 25 μm.

In addition, regulation of the surface roughness Ra of the light diffusion layer 20 was carried out by changing the amount ratio of the binder to the light diffusing agent in the coating composition for forming the light diffusion layer 20. In addition, regulation of the adhesion force between the second protective film 28 and the light diffusion layer 20 was carried out by changing the curing state through regulation of the irradiation dose of ultraviolet rays at the time of forming the adhesive layer 24.

### Comparative Example 1

In the same manner as in Example 19 except that the second protective film 28 was not included, a gas barrier film was manufactured.

### Comparative Example 2

In the same manner as in Example 19 except that the second protective film did not have the adhesive layer 24 and only had the support 26 attached thereon by electrostatic adsorption, a gas barrier film was manufactured.

[Evaluation]

With respect to the gas barrier film 30 manufactured as above, the second protective film 28 was peeled from the manufactured gas barrier film 30 and the following evaluation was carried out.

<Gas Barrier Properties>The water vapor permeability (WVTR) in the gas barrier film 30 having the second protective film 28 peeled therefrom at 40° C. and 90% RH was measured by AQUATRAN (MODEL-1) manufactured by MOCON Inc.

A water vapor permeability of less than 1×10⁻³ g/(m²·day) was evaluated as AA;

a water vapor permeability of 1×10⁻³ g/(m²·day) or more and less than 3×10⁻³ g/(m²·day) was evaluated as A;

a water vapor permeability of 3×10⁻³ g/(m²·day) or more and less than 6×10⁻³ g/(m²·day) was evaluated as B;

a water vapor permeability is 6×10⁻³ g/(m²·day) or more and less than 9×10⁻³ g/(m²·day) was evaluated as C; and

a water vapor permeability of 9×10⁻³ g/(m²·day) or more was evaluated as D. Cases evaluated as AA to C have no problems in most of applications, but cases evaluated as D have practical problems in many cases.

<Transmittance>

The average value of overall light transmittance (400 to 800 nm) of the gas barrier film 30 having the second protective film 28 peeled therefrom was measured in accordance with JIS K 7361, using NDH5000 manufactured by Nippon Denshoku Industries Co., Ltd.

An overall light transmittance of 88% or more was evaluated as A;

an overall light transmittance of 80% or more and less than 88% was evaluated as B;

an overall light transmittance of 70% or more and less than 80% was evaluated as C; and

an overall light transmittance of less than 70% was evaluated as D.

Cases evaluated as A to C have no problems in most of applications, but cases evaluated as D have practical problems in many cases.

<Comprehensive Evaluation>

In the evaluations of the gas barrier properties and the transmittance,

a case where both of the gas barrier properties and the transmittance were A or more was evaluated as A;

a case where at least one of the gas barrier properties or the transmittance was B was evaluated as B;

a case where at least one of the gas barrier properties or the transmittance was C was evaluated as C; and

a case where at least one of the gas barrier properties or the transmittance was D was evaluated as D.

Cases evaluated as A to C have no problems in most of applications, but Cases evaluated as D have practical problems in many cases.

The results are shown in the following table.

TABLE 1

| | | | Thickness | | | | Overall light | | |
|---|---|---|---|---|---|---|---|---|---|
| | Diffusion | | of | | | | transmittance | | |
| | layer | Adhesion | adhesive | | Gas barrier properties | | Measured | | |
| | Ra | force | layer | Adhesion | WVTR | | value | | Overall |
| | [μm] | [N/25 mm] | [μm] | coefficient | [g/(m² · day)] | Evaluation | [%] | Evaluation | evaluation |
| Example 1 | 1 | 0.1 | 1 | 0.1 | 8 × 10⁻³ | C | 89.5 | A | C |
| Example 2 | | | 10 | 1 | 4.4 × 10⁻³ | B | 88.9 | A | B |
| Example 3 | | | 25 | 2.5 | 2.7 × 10⁻³ | A | 88.3 | A | A |
| Example 4 | | 0.5 | 1 | 0.5 | 6.6 × 10⁻³ | C | 89.1 | A | C |
| Example 5 | | | 10 | 5 | 1.5 × 10⁻³ | A | 83.3 | B | B |
| Example 6 | | | 25 | 12.5 | 9.8 × 10⁻⁴ | AA | 74.5 | C | C |
| Example 7 | | 1 | 1 | 1 | 4.4 × 10⁻³ | B | 88.9 | A | B |
| Example 8 | | | 10 | 10 | 9.9 × 10⁻⁴ | AA | 76.4 | C | C |
| Example 9 | | | 25 | 25 | 9.5 × 10⁻⁴ | AA | 70.3 | C | C |
| Example 10 | 3.5 | 0.1 | 1 | 0.03 | 8.2 × 10⁻³ | C | 89.5 | A | C |
| Example 11 | | | 10 | 0.29 | 7.2 × 10⁻³ | C | 89.3 | A | C |
| Example 12 | | | 25 | 0.71 | 6.2 × 10⁻³ | C | 89.0 | A | C |
| Example 13 | | 0.5 | 1 | 0.14 | 7.8 × 10⁻³ | C | 89.4 | A | C |
| Example 14 | | | 10 | 1.43 | 3.9 × 10⁻³ | B | 88.7 | A | B |
| Example 15 | | | 25 | 3.57 | 2.1 × 10⁻³ | A | 86.5 | B | B |
| Example 16 | | 1 | 1 | 0.29 | 7.2 × 10⁻³ | C | 89.3 | A | C |
| Example 17 | | | 10 | 2.86 | 2.5 × 10⁻³ | A | 87.9 | B | B |
| Example 18 | | | 25 | 7.14 | 1.2 × 10⁻³ | A | 80.2 | B | B |
| Example 19 | 7 | 0.1 | 1 | 0.01 | 8.5 × 10⁻³ | C | 89.6 | A | C |
| Example 20 | | | 10 | 0.14 | 7.8 × 10⁻³ | C | 89.4 | A | C |
| Example 21 | | | 25 | 0.36 | 6.9 × 10⁻³ | C | 89.2 | A | C |
| Example 22 | | 0.5 | 1 | 0.07 | 8.1 × 10⁻³ | C | 89.5 | A | C |
| Example 23 | | | 10 | 0.71 | 6.2 × 10⁻³ | C | 89.0 | A | C |
| Example 24 | | | 25 | 1.79 | 3.5 × 10⁻³ | B | 88.5 | A | B |
| Example 25 | | 1 | 1 | 0.14 | 7.8 × 10⁻³ | C | 89.4 | A | C |
| Example 26 | | | 10 | 1.43 | 3.9 × 10⁻³ | B | 88.7 | A | B |
| Example 27 | | | 25 | 3.57 | 2 × 10⁻³ | A | 86.5 | B | B |
| Comparative | 7 | — | — | — | 6.8 × 10⁻² | D | 88.6 | A | D |
| Example 1 | | | | | | | | | |
| Comparative | 7 | — | — | — | 8.7 × 10⁻² | D | 84.4 | B | D |
| Example 2 | | | | | | | | | |

As shown in the above table, in Comparative Example 1 in which the second protective film 28 was not included and in Comparative Example 2 in which the second protective film did not have an adhesive layer, it is thought that a local load was applied to the inorganic layer 16, due to the unevenness of the light diffusion layer 20, and accordingly, the inorganic layer 16 was damaged and the gas barrier properties were deteriorated at the time of the winding of the gas barrier film, the transport in formation of the adhesion layer 32, the winding after formation of the adhesion layer 32, or the like.

Furthermore, in Examples 1, 4, 10 to 13, 16, 19 to 23, and 25, the adhesion coefficient is lower that the more preferred range (1 to 7), it is thought that since the adhesion force of the second protective film 28 was lower than that in Example 3 in which the adhesion coefficient was in the more preferred range, and the like, partial peeling of the second protective film 28 occurred at the time of the transport in formation of the adhesion layer 32, and as a result, some damages were generated in the inorganic layer 16, and thus, the gas barrier properties were lowered, as compared with Example 3 and the like.

Moreover, in Examples 6, 8, and 9, it is thought that since the adhesion coefficient was higher than the more preferred range, and the adhesion force of the second protective film 28 was stronger than that in Example 3 in which the adhesion coefficient was in the more preferred range, and the like, partial peeling of the adhesive layer 24 occurred at the time of the peeling of the second protective film 28, and as a result, the overall light transmittance was lowered, as compared with Example 3 and the like.

However, even in these Examples, there are no practical problems in most of the applications as described above.

In addition, in Examples 2 to 3, 5, 7, 14 to 15, 17 to 18, 24, and 26 to 27 in which adhesion coefficients were in the more preferred range, excellent results were obtained in terms of both the gas barrier properties and the overall light transmittance.

From the above results, the effect of the present invention is apparent.

### INDUSTRIAL APPLICABILITY

The present invention can be suitably used in a quantum dot film for use in the backlight of an LCD, a protective film requiring light diffusing properties, and the like.

### EXPLANATION OF REFERENCES

10, 30: gas barrier films

12: substrate

14: organic layer

16: inorganic layer

18: first protective film

20: light diffusion layer

24: adhesive layer

26: support

28: second protective film

32: adhesion layer

34: quantum dot film

38: quantum dot layer

What is claimed is:

1. A functional film comprising:
a substrate;
a first functional layer having one or more combinations of an inorganic layer and an organic layer serving as a base substrate of the inorganic layer, formed on one surface of the substrate;
a functional layer-side surface layer formed on the surface of the first functional layer, with the surface being on the side opposite to the substrate;
a light diffusion layer formed on the surface of the substrate, with the surface being on the side opposite to the surface on which the first functional layer is formed; and
a diffusion layer-side surface layer having a support and an adhesive layer, formed on the surface of the light diffusion layer.

2. A functional film comprising:
a substrate;
a first functional layer having one or more combinations of an inorganic layer and an organic layer serving as a base substrate of the inorganic layer, formed on one surface of the substrate;
a second functional layer formed on the surface of he first functional layer, with the surface being on the side opposite to the substrate;
a light diffusion layer formed on the surface of the substrate, with the surface being on the side opposite to the surface on which the first functional layer is formed; and
a diffusion layer-side surface layer having a support and an adhesive layer, formed on the surface of the light diffusion layer.

3. The functional film according to claim 2, wherein the second functional layer is an adhesion layer.

4. A functional film comprising:
a functional film including a substrate, a first functional layer having one or more combinations of an inorganic layer and an organic layer serving as a base substrate of the inorganic layer, formed on one surface of the substrate, a light diffusion layer formed on the surface of the substrate, with the surface being on the side opposite to the surface on which the first functional layer is formed, and a diffusion layer-side surface layer having a support and an adhesive layer, formed on the surface of the light diffusion layer;
a gas barrier film; and
a quantum dot layer sandwiched between the functional film and the gas barrier film, with the diffusion layer-side surface layer of the functional film being on the outer side.

5. The functional film according to claim 4, wherein the gas barrier film has a substrate and one or more combinations of an inorganic layer and an organic layer serving as a base substrate of the inorganic layer, formed on one surface of the substrate, and the substrate is on the outer side.

6. The functional film according to claim 4, wherein the adhesion layer is included at least one of between the functional film and the quantum dot layer, or between the gas barrier film and the quantum dot layer.

7. A method for producing a functional film, comprising:
a step of forming a first functional layer having one or more combinations of an inorganic layer and an organic layer serving as a base substrate of the inorganic layer, on one surface of a substrate;
a step of forming a functional layer-side surface layer on the surface of the first functional layer, with the surface being on the side opposite to the substrate;
a step of forming a light diffusion layer on the surface of the substrate, with the surface being on the side opposite to the surface on which the first functional layer is formed, after forming the functional layer-side surface layer; and
a step of forming a diffusion layer-side surface layer having a support and an adhesive layer, on the surface of the light diffusion layer.

8. The method for producing a functional film according to claim 7, further comprising a step of peeling the functional layer-side surface layer.

9. The method for producing a functional film according to claim 8, further comprising a step of forming a second functional layer on the surface of the first functional layer, with the surface being on the side opposite to the substrate.

10. The method for producing a functional film according to claim 9, wherein the second functional layer is an adhesion layer.

11. The method for producing a functional film according to claim 8, further comprising:
a step of applying a composition serving as a quantum dot layer on the outermost surface on the side having the first functional layer formed thereon and laminating a gas barrier film on the surface of the composition, or a step of applying a composition serving as a quantum dot layer on the surface of the gas barrier film, laminating a functional film on the surface of the composition while the first functional layer is arranged to face the composition; and
a step of curing the composition.

12. The method for producing a functional film according to claim 11, wherein the gas barrier film has a substrate and one or more combinations of an inorganic layer and an organic layer serving as a base substrate of the inorganic layer, formed on one surface of the substrate, and the surface on which the organic layer and the inorganic layer are formed is on the composition side.

13. The method for producing a functional film according, to claim 11, wherein the gas barrier film has the adhesion layer on the outermost surface.

14. The method for producing a functional film according to claim 7, further comprising a step of peeling the diffusion layer-side surface layer.
